(19) United States
(12) Patent Application Publication
(10) Pub. No.: US 2026/0271693 A1
(43) Pub. Date: Sep. 10, 2026

(54) BONDED ASSEMBLIES INCLUDING THROUGH-DIE VIA STRUCTURES AND METHODS FOR FORMING THE SAME

(71) Applicant: Sandisk Technologies, Inc., Milpitas, CA (US)

(72) Inventors: Mitsuteru MUSHIGA, Yokkaichi (JP); Akio NISHIDA, Yokkaichi (JP); Masaaki HIGASHITANI, Cupertino, CA (US)

(21) Appl. No.: 19/071,286

(22) Filed: Mar. 5, 2025

(51) Int. Cl. H01L 23/48; H01L 21/768; H01L 23/00; H01L 23/522; H01L 23/528; H01L 25/18; H10B 80/00; H10D 80/30

(52) U.S. Cl. CPC H10W 20/20; H10B 80/00; H10D 80/30; H10W 20/089; H10W 20/42; H10W 20/43; H10W 20/435; H10W 90/00; H10W 20/076; H10W 72/90; H10W 80/312; H10W 80/327; H10W 90/20; H10W 90/297

(57) ABSTRACT

A semiconductor structure includes a first bonded assembly including a first memory die and a first memory-controller die which is bonded to the first memory die; a second bonded assembly bonded to the first bonded assembly at a first bonding interface and including a second memory die and a second memory-controller die; and a first through-die contact via structure vertically extending through the first memory die and the first memory-controller die, through the first bonding interface, and through at least one dielectric material layer within the second bonded assembly and contacting an interconnect structure within the second bonded assembly.

### FIELD

The present disclosure relates generally to the field of semiconductor devices, and particularly to semiconductor structures including composite dies containing through-die via structures and methods for forming the same.

### BACKGROUND

Flash memory devices include NAND and NOR memory devices. Such memory devices may be formed by sequentially depositing memory device layers over a driver circuit located on a silicon wafer.

### SUMMARY

According to an aspect of the present disclosure, a semiconductor structure comprises: a first bonded assembly including a first memory die and a first memory-controller die which is bonded to the first memory die, wherein the first memory die includes a first alternating stack of first insulating layers and first electrically conductive layers and first memory stack structures vertically extending through the first alternating stack and comprising a three-dimensional array of first memory elements, and wherein the first memory-controller die includes a first memory controller circuit configured to control operation of the three-dimensional array of first memory elements; a second bonded assembly bonded to the first bonded assembly at a first bonding interface and including a second memory die and a second memory-controller die, wherein the second memory die includes a second alternating stack of second insulating layers and second electrically conductive layers and second memory stack structures vertically extending through the second alternating stack and comprising a three-dimensional array of second memory elements, and wherein the second memory-controller die includes a second memory controller circuit configured to control operation of the three-dimensional array of second memory elements; and a first through-die contact via structure vertically extending through the first memory die, the first memory-controller die, the first bonding interface, and at least one dielectric material layer within the second bonded assembly, and contacting an interconnect structure within the second bonded assembly.

According to another aspect of the present disclosure, a method of forming a semiconductor structure is provided. The method comprises: providing a first bonded assembly including a first memory die and a first memory-controller die which is bonded to the first memory die, wherein the first memory die includes a first alternating stack of first insulating layers and first electrically conductive layers and first memory stack structures vertically extending through the first alternating stack and comprising a three-dimensional array of first memory elements, and wherein the first memory-controller die includes a first memory controller circuit configured to control operation of the three-dimensional array of first memory elements; providing a second bonded assembly including a second memory die and a second memory-controller die, wherein the second memory die includes a second alternating stack of second insulating layers and second electrically conductive layers and second memory stack structures vertically extending through the second alternating stack and comprising a three-dimensional array of second memory elements, and wherein the second memory-controller die includes a second memory controller circuit configured to control operation of the three-dimensional array of second memory elements; fusion bonding the second bonded assembly to the first bonded assembly, wherein the second bonded assembly contacts the first bonded assembly at a first bonding interface; and forming a first through-die contact via structure that continuously extends through the first memory die, the first memory-controller die, the first bonding interface, and at least one dielectric material layer within the second bonded assembly directly to an interconnect structure within the second bonded assembly.

### BRIEF DESCRIPTION OF THE DRAWINGS

FIG. 1 is a schematic vertical cross-sectional view of a region of an exemplary in-process memory die after formation of a backside dielectric layer, in-process source-level material layers, an alternating stack of insulating layers and sacrificial material layers having stepped surfaces, and a retro-stepped dielectric material portion over a carrier substrate according to an embodiment of the present disclosure.

FIG. 2A is a schematic vertical cross-sectional view of a region of the exemplary in-process memory die after forming memory openings according to an embodiment of the present disclosure. FIG. 2B is a top-down view of the exemplary in-process memory die of FIG. 2A. The vertical plane A-A′ is the cut plane of the vertical cross-sectional view of FIG. 2A. FIG. 2C is a top-down view of the exemplary in-process memory die at the processing steps of FIGS. 2A and 2B.

FIGS. 3A-3D are sequential vertical cross-sectional views of a memory opening during formation of a memory opening fill structure according to an embodiments of the present disclosure.

FIG. 4 is a vertical cross-sectional view of a region of the exemplary in-process memory die after formation of memory opening fill structures according to an embodiment of the present disclosure.

FIG. 5A is a vertical cross-sectional view of a region of the exemplary in-process memory die after formation of a contact-level dielectric layer, a patterned hard mask layer, lateral isolation trenches, and discrete through-stack openings according to an embodiment of the present disclosure. FIG. 5B is a top-down view of a region of the exemplary in-process memory die of FIG. 5A. The vertical plane A-A′ is the cut plane of the vertical cross-sectional view of FIG. 5A. FIG. 5C is a top-down view of the exemplary in-process memory die including the exemplary in-process memory die at the processing steps of FIGS. 5A and 5B.

FIG. 6 is a vertical cross-sectional view of a region of the exemplary in-process memory die after vertical extension of the discrete through-stack openings according to an embodiment of the present disclosure.

FIG. 7 is a vertical cross-sectional view of a region of the exemplary in-process memory die after formation of sacrificial lateral isolation trench fill structures and sacrificial through-stack opening fill structures according to an embodiment of the present disclosure.

FIG. 8 is a vertical cross-sectional view of a region of the exemplary in-process memory die after removal of the sacrificial lateral isolation trench fill structures according to an embodiment of the present disclosure.

FIG. 9 is a vertical cross-sectional view of a region of the exemplary in-process memory die after formation of a source cavity according to an embodiment of the present disclosure.

FIG. 10 is a vertical cross-sectional view of a region of the exemplary in-process memory die after formation of a source contact layer and dielectric capping liners according to an embodiment of the present disclosure.

FIG. 11 is a vertical cross-sectional view of a region of the exemplary in-process memory die after formation of laterally-extending cavities according to an embodiment of the present disclosure.

FIG. 12 is a vertical cross-sectional view of a region of the exemplary in-process memory die after formation of electrically conductive layers according to an embodiment of the present disclosure.

FIG. 13 is a vertical cross-sectional view of a region of the exemplary in-process memory die after formation of lateral isolation trench fill structures and contact via structures according to an embodiment of the present disclosure.

FIG. 14 is a vertical cross-sectional view of a region of the exemplary in-process memory die after removal of the sacrificial through-stack opening fill structures according to an embodiment of the present disclosure.

FIG. 15 is a vertical cross-sectional view of a region of the exemplary in-process memory die after formation of tubular dielectric spacers and through-stack via structures according to an embodiment of the present disclosure.

FIG. 16 is a vertical cross-sectional view of a region of the exemplary in-process memory die after formation of layer contact via structures, drain contact via structures, and peripheral connection via structures according to an embodiment of the present disclosure.

FIG. 17 is a vertical cross-sectional view of a region of the exemplary in-process memory die after formation of a memory die according to an embodiment of the present disclosure.

FIG. 18 is a vertical cross-sectional view of a region of an exemplary memory-controller die after formation of controller semiconductor devices and controller lower-level dielectric material layers according to an embodiment of the present disclosure.

FIG. 19 is a vertical cross-sectional view of a region of the exemplary memory-controller die after formation of a memory-controller die according to an embodiment of the present disclosure.

FIG. 20 is a vertical cross-sectional view of a region of a first exemplary bonded assembly of a memory die and a memory-controller die according to an embodiment of the present disclosure.

FIG. 21 is a vertical cross-sectional view of a region of the first exemplary bonded assembly after removal of a carrier substrate from the memory die according to an embodiment of the present disclosure.

FIG. 22 is a vertical cross-sectional view of a region of the first exemplary bonded assembly after formation of backside via openings according to an embodiment of the present disclosure.

FIG. 23 is a vertical cross-sectional view of a region of the first exemplary bonded assembly after formation of source-side interconnect structures according to an embodiment of the present disclosure.

FIG. 24 is a vertical cross-sectional view of a region of the first exemplary bonded assembly after formation of source-side memory-die dielectric material layers and thinning of a semiconductor substrate of the memory-controller die according to an embodiment of the present disclosure.

FIG. 25 is a vertical cross-sectional view of a region of the first exemplary bonded assembly after thinning the controller-die semiconductor substrate according to an embodiment of the present disclosure.

FIG. 26 is a vertical cross-sectional view of a first exemplary structure including a composite die containing two bonded assemblies of a respective memory die and a respective memory-controller die according to an embodiment of the present disclosure.

FIG. 27 is a vertical cross-sectional view of the first exemplary structure after formation of contact via cavities according to an embodiment of the present disclosure.

FIG. 28 is a vertical cross-sectional view of the first exemplary structure after formation of contact via structures according to an embodiment of the present disclosure.

FIG. 29 is a vertical cross-sectional view of a second exemplary structure including a composite die containing two bonded assemblies of a respective memory die and a respective memory-controller die according to an embodiment of the present disclosure.

FIG. 30 is a vertical cross-sectional view of the second exemplary structure after formation of contact via cavities according to an embodiment of the present disclosure.

FIG. 31 is a vertical cross-sectional view of the second exemplary structure after formation of contact via structures according to an embodiment of the present disclosure.

FIG. 32 is a vertical cross-sectional view of a third exemplary structure including a composite die containing three bonded assemblies of a respective memory die and a respective memory-controller die according to an embodiment of the present disclosure.

FIG. 33 is a vertical cross-sectional view of the third exemplary structure after formation of contact via cavities according to an embodiment of the present disclosure.

FIG. 34 is a vertical cross-sectional view of the third exemplary structure after formation of contact via structures according to an embodiment of the present disclosure.

FIG. 35 is a vertical cross-sectional view of a fourth exemplary structure including a composite die containing two bonded assemblies of a respective memory die and a respective memory-controller die according to an embodiment of the present disclosure.

FIG. 36 is a vertical cross-sectional view of the fourth exemplary structure after formation of primary-direction contact via structures according to an embodiment of the present disclosure.

FIG. 37 is a vertical cross-sectional view of the fourth exemplary structure after formation of counter-direction contact via structures according to an embodiment of the present disclosure.

FIG. 38 is a vertical cross-sectional view of a fifth exemplary structure including a composite die containing two bonded assemblies of a respective memory die and a respective memory-controller die according to an embodiment of the present disclosure.

FIG. 39 is a vertical cross-sectional view of the fifth exemplary structure after formation of primary-direction contact via structures according to an embodiment of the present disclosure.

FIG. 40 is a vertical cross-sectional view of the fifth exemplary structure after formation of counter-direction contact via structures according to an embodiment of the present disclosure.

FIG. 41A-41H are vertical cross-sectional views of steps of forming a sixth exemplary structure according to an embodiment of the present disclosure.

FIG. 42A is a vertical cross-sectional view of an exemplary structure including multiple instances of composite dies according to an embodiment of the present disclosure. FIG. 42B is a vertical cross-sectional view of another exemplary structure including multiple instances of composite dies according to an embodiment of the present disclosure.

### DETAILED DESCRIPTION

As discussed above, the embodiments of the present disclosure are directed to semiconductor structures including composite dies containing through-die via structures and methods for forming the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which may be the smallest unit that can be erased in a single erase operation. Alternatively, subblocks may be the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As Used Herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

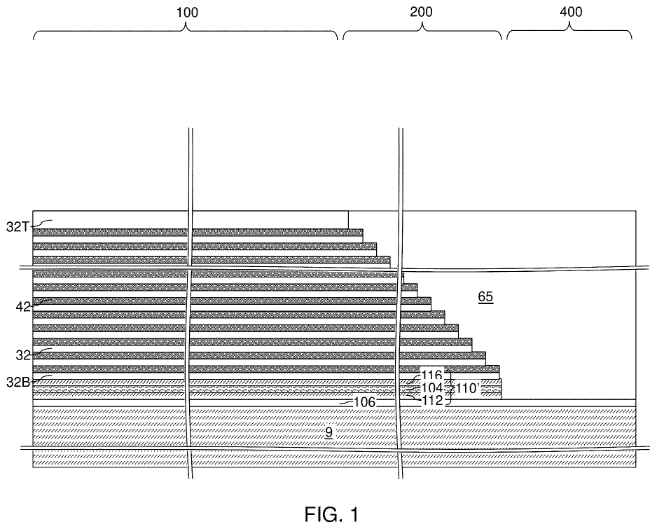

Referring to FIG. 1, an exemplary in-process memory die according to an embodiment of the present disclosure is illustrated. The exemplary in-process memory die comprises a carrier substrate 9, which may be a semiconductor substrate, a dielectric substrate, or a conductive substrate. For example, the carrier substrate 9 may comprise a commercially available silicon wafer. Alternatively, the carrier substrate 9 may comprise any material that may be removed selectively to the materials of a first memory-die proximal dielectric material layer 106 and a retro-stepped dielectric material portion 65 to be subsequently formed.

A dielectric material layer can be formed on a top surface of the carrier substrate 9. The dielectric material layer can be subsequently employed as a stopping material layer for a process that removes the carrier substrate 9, and is herein referred to as a first memory-die proximal dielectric material layer 106, or as a stopper dielectric layer. The first memory-die proximal dielectric material layer 106 comprises and/or consists essentially of a dielectric material, such as undoped silicate glass (i.e., silicon oxide), a doped silicate glass, or silicon nitride. If a polishing process such as a chemical mechanical polishing process is employed to subsequently remove the carrier substrate 9, the first memory-die proximal dielectric material layer 106 may be subsequently employed as a polishing stopper material layer. If an etch process such as a wet etch process is employed to subsequently remove the carrier substrate 9, the first memory-die proximal dielectric material layer 106 may be subsequently employed as an etch stop material layer. In one embodiment, the first memory-die proximal dielectric material layer 106 comprises a dielectric material such as undoped silicate glass, a doped silicate glass, or silicon nitride. The thickness of the first memory-die proximal dielectric material layer 106 may be in a range from 50 nm to 600 nm, such as from 100 nm to 300 nm, although lesser and greater thicknesses may also be employed.

In-process source-level material layers 110′ can be formed over the first memory-die proximal dielectric material layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner (not shown), a source-level sacrificial layer 104, an optional upper sacrificial liner (not shown), and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The Source-level Sacrificial Layer 104 Includes a Sacrificial Material That May Be removed selectively to the lower sacrificial liner (or selectively to the lower source-level semiconductor layer 112) and the upper sacrificial liner (or selectively to the upper source-level semiconductor layer 116). In one embodiment, the source-level sacrificial layer 104 may include a semiconductor material such as undoped amorphous silicon or a silicon-germanium alloy with an atomic concentration of germanium greater than 20 %. The thickness of the source-level sacrificial layer 104 may be in a range from 30 nm to 400 nm, such as from 60 nm to 200 nm, although lesser and greater thicknesses may also be used. The lower sacrificial liner (if present) and the upper sacrificial liner (if present) include materials that may function as an etch stop material during removal of the source-level sacrificial layer 104. For example, the lower sacrificial liner and the upper sacrificial liner may include silicon oxide, silicon nitride, and/or a dielectric metal oxide. In one embodiment, each of the lower sacrificial liner and the upper sacrificial liner may include a silicon oxide layer having a thickness in a range from 2 nm to 30 nm, although lesser and greater thicknesses may also be used.

An alternating stack of first material layers and second material layers can be formed over the in-process source-level material layers 110′. In an alternative embodiment, the in-process source-level material layers 110′ and the first memory-die proximal dielectric material layer 106 may be omitted, and the alternating stack is formed directly on a surface of the carrier substrate 9. In the alternating stack, the first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9, and is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about twice the thickness of other insulating layers 32.

Stepped surfaces are formed in a contact region 200. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

The exemplary in-process memory die comprises a memory array region 100 in which each layer within the alternating stack (32, 42) is present and in which a three-dimensional array of memory elements is to be subsequently formed, the contact region 200 which contains the stepped surfaces of the alternating stack (32, 42) and in which layer contact via structures contacting word lines are to be subsequently formed, and a peripheral region 400 in which the layers within the alternating stack (32, 42) are absent. The peripheral region 400 may comprise a kerf region through which the memory dies will be diced and an edge seal region. Openings may be formed through the in-process source-level material layers 110′ in the peripheral region 400 for formation of edge seal structures.

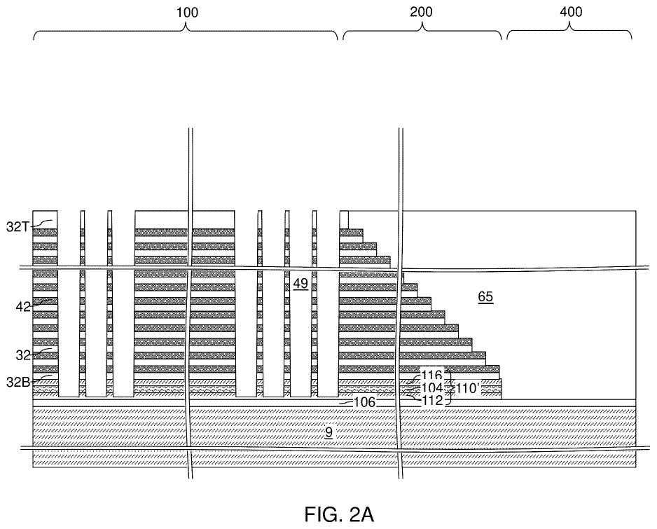

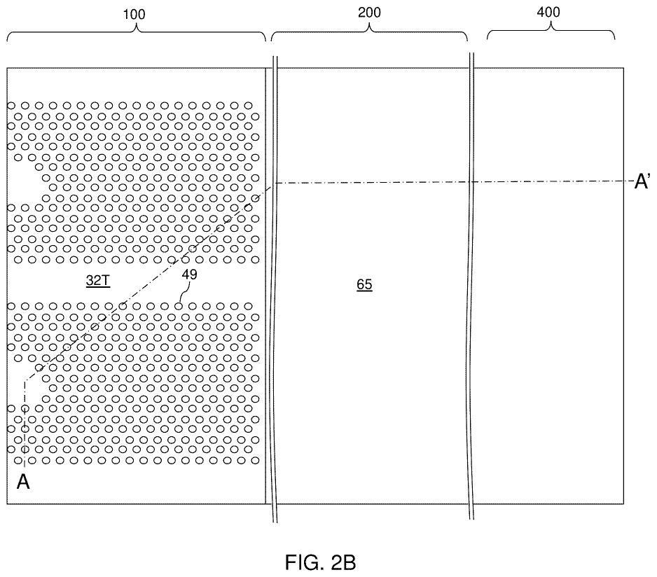

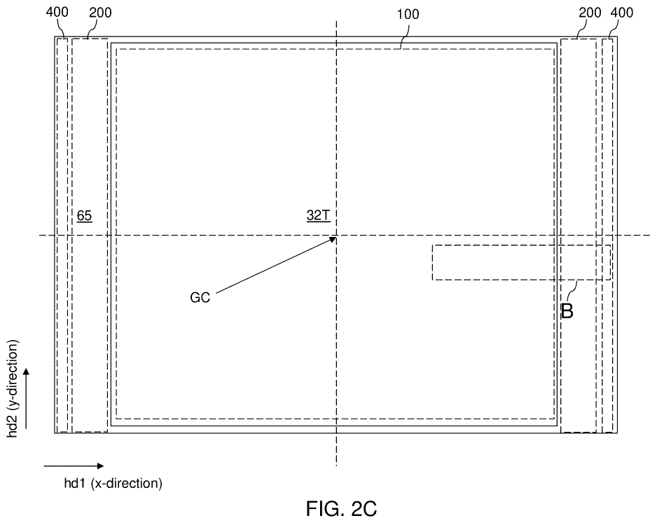

Referring to FIG. 2A-2C, various views of the exemplary in-process memory die are illustrated after formation of memory openings 49. FIG. 2C is a top-down view of the exemplary in-process memory die that illustrates an entire area of an in-process memory die. FIG. 2B is a top-down view of region B of the top-down view of the exemplary in-process memory die shown in FIG. 2C. FIG. 2A is a vertical cross-sectional view of the exemplary in-process memory die along the vertical plane A-A′ of FIG. 2B. The in-process memory die may have a rectangular shape in a plan view, such as the top-down view of FIG. 2C. The geometrical center GC of the in-process memory die is also illustrated in FIG. 2C. As used herein, a geometrical center of an element refers to a center of gravity of a hypothetical object occupying the same volume as the element and having a uniform density throughout.

Specifically, an etch mask layer (not shown) can be formed over the alternating stack (32, 42) and the retro-stepped dielectric material portion 65, and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings (not illustrated) that are formed in the contact region 200. Each of the memory openings 49 and the support openings can vertically extend through the alternating stack (32, 42) and into the in-process source-level material layers 110′ In one embodiment, bottom surfaces of the memory openings 49 and the support openings may be formed within the lower source-level semiconductor layer 112 or at an interface between the lower source-level semiconductor layer and the first memory-die proximal dielectric material layer 106.

The support openings may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed.

In one embodiment, the memory array region 100 may be laterally spaced apart from the contact region 200 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

Sacrificial memory opening fill structures (not shown) can be formed in the memory openings 49. The sacrificial memory opening fill structures may comprise a carbon-based material (such as amorphous carbon or diamond-like carbon), a semiconductor material (such as amorphous silicon or polysilicon), a dielectric fill material (such as borosilicate glass or organosilicate glass), or an organic material. A dielectric fill material can be deposited in the support openings to form support pillar structures (not shown). The sacrificial memory opening fill structures can be subsequently removed to form cavities in the memory openings 49.

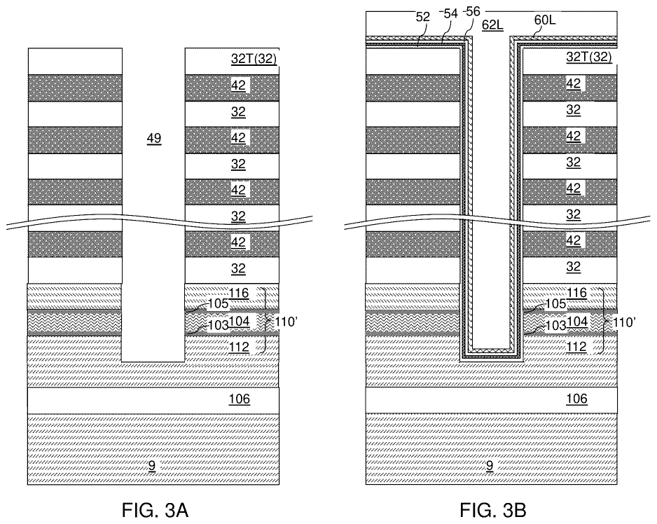

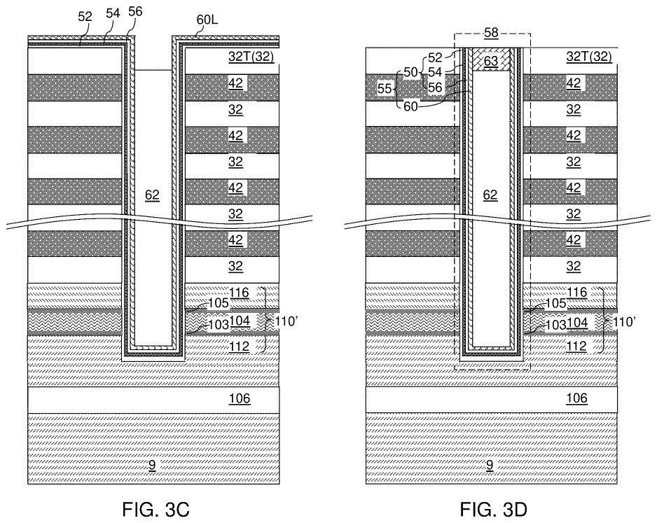

FIGS. 3A-3D are sequential vertical cross-sectional views of a memory opening 49 during formation of a NAND string (e.g., a dummy NAND string or a data storage NAND string) which is referred to below as a “memory opening fill structure” 58 according to an embodiment of the present disclosure.

Referring to FIG. 3A, a memory opening 49 is illustrated after the processing steps of FIGS. 2A-2C .

Referring to FIG. 3B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride). In case the memory material layer 54 comprises a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹⁷/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 3C, the dielectric core layer 62L can be vertically recessed such that each remaining portion of the dielectric core layer 62L has a top surface at, or about, the horizontal plane including the bottom surface of the topmost insulating layer 32T. Each remaining portion of the dielectric core layer 62L constitutes a dielectric core 62.

Referring to FIG. 3D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42.

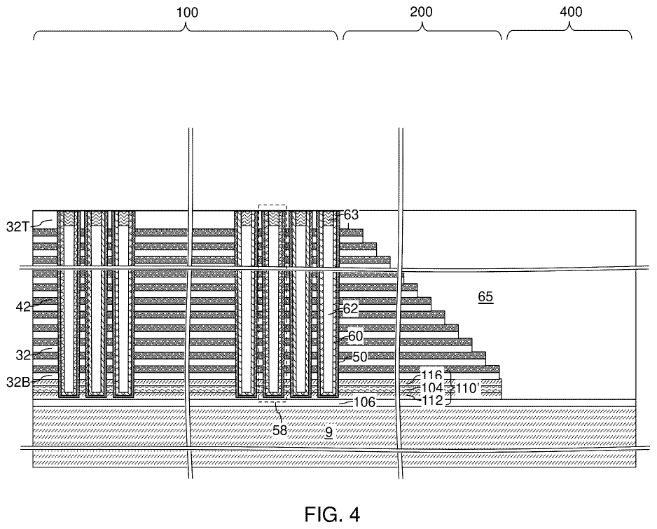

Referring to FIG. 4, the exemplary in-process memory die is illustrated after formation of memory opening fill structures 58 within the memory openings 49. Each of the memory opening fill structures 58 may comprise a memory stack structure 55, which comprises a memory film 50 and a vertical semiconductor channel 60. A combination of an alternating stack (32, 42) of insulating layers 32 and sacrificial material layers 42, memory openings 49 vertically extending through the alternating stack (32, 42), and memory opening fill structures 58 located in the memory openings 49 can be formed. Each of the memory opening fill structures 58 comprises a respective vertical stack of memory elements, such as portions of a memory material layer 54 located at levels of the sacrificial material layers 42.

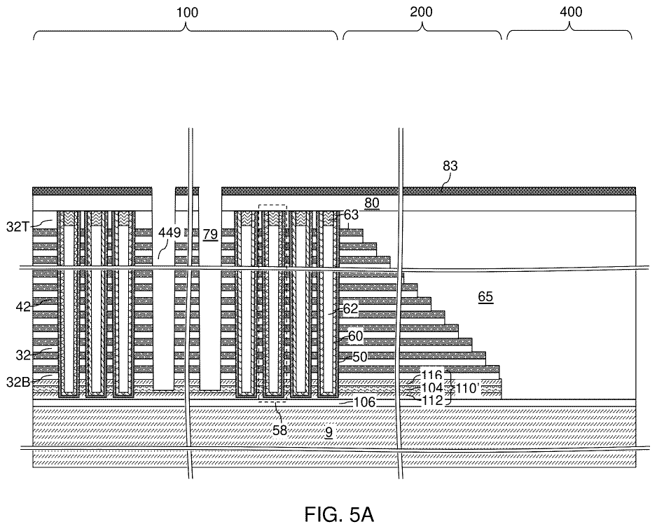

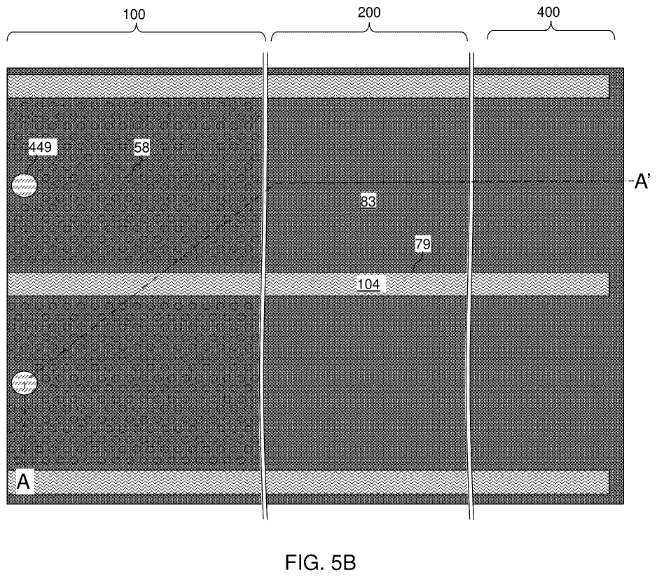

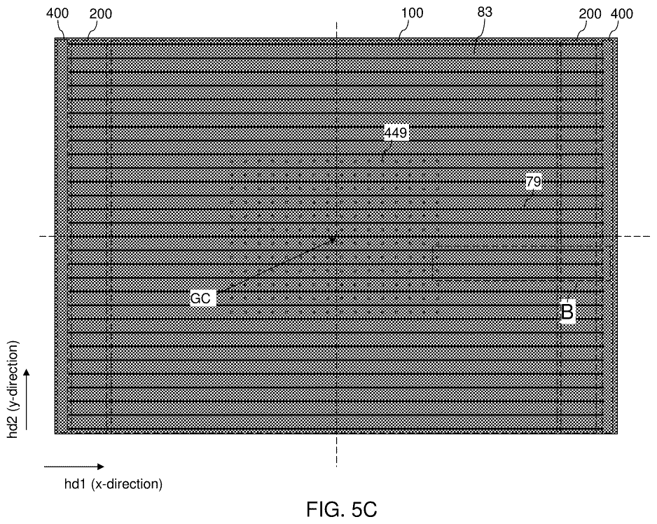

Referring to FIGS. 5A-5C , various views of the exemplary are illustrated after formation of a contact-level dielectric layer 80, a patterned hard mask layer 83, lateral isolation trenches 79, and through-stack openings 449. FIG. 5C is a top-down view of the exemplary in-process memory die that illustrates an entire area of an in-process memory die. FIG. 5B is a top-down view of region B of the top-down view of the exemplary in-process memory die shown in FIG. 5C. FIG. 5A is a vertical cross-sectional view of the exemplary in-process memory die along the vertical plane A-A′ of FIG. 5B.

Specifically, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A hard mask material can be deposited over the contact-level dielectric layer 80, and can be patterned to form a patterned hard mask layer 83. The hard mask layer 83 may comprise any suitable hard mask material, such as titanium nitride, polysilicon, silicon nitride, etc. The pattern of the openings in the patterned hard mask layer 83 may comprise elongated openings that laterally extend along the first horizontal direction hd1 between neighboring clusters (e.g., memory blocks) of memory opening fill structures 58 through the memory array region 100 and a pair of contact regions 200, and discrete openings having circular horizontal cross-sectional shapes.

An anisotropic etch process can be performed to transfer the pattern of the openings in the patterned hard mask layer 83 through the contact-level dielectric layer 80, the alternating stack (32, 42), the retro-stepped dielectric material portion 65, and upper layers of the in-process source-level material layers 110'. Lateral isolation trenches 79 laterally extending along the first horizontal direction hd1 can be formed through the alternating stack (32, 42), the retro-stepped dielectric material portion 65, the contact-level dielectric layer 80, and upper layers of the in-process source-level material layers 110′ underneath the elongated openings in the patterned hard mask layer 83. Through-stack openings 449 can be formed through the alternating stack (32, 42), the retro-stepped dielectric material portion 65, the contact-level dielectric layer 80, and upper layers of the in-process source-level material layers 110′ underneath the discrete openings in the patterned hard mask layer 83. In one embodiment, bottom surfaces of the lateral isolation trenches 79 and the through-stack openings 449 may comprise surface segments of the source-level sacrificial layer 104. In one embodiment, the through-stack openings 449 may be arranged as a two-dimensional periodic array. In one embodiment, the through-stack openings 449 may be formed in a center region of the in-process memory die in a plan view. In one embodiment, peripheral regions of the in-process memory die may be free of any through-stack openings 449.

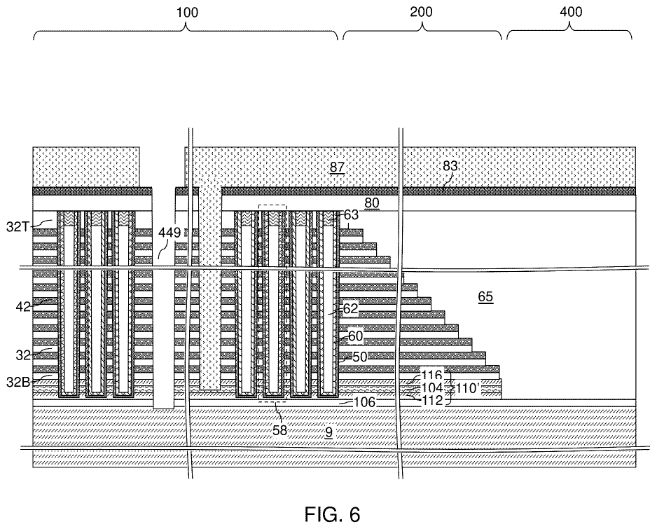

Referring to FIG. 6, a photoresist layer 87 can be applied over the exemplary in-process memory die, and can be lithographically patterned to form openings around the through-stack openings 449. The photoresist layer 87 can cover all areas of the lateral isolation trenches 79. An anisotropic etch process can be performed to vertically extend the through-stack openings 449 through the in-process source-level material layers 110′ and the first memory-die proximal dielectric material layer 106 and optionally into an upper portion of the carrier substrate 9. The photoresist layer 87 can be subsequently removed, for example, by ashing. The patterned hard mask layer 83 can be removed selectively to the contact-level dielectric layer, for example, by performing a wet etch process.

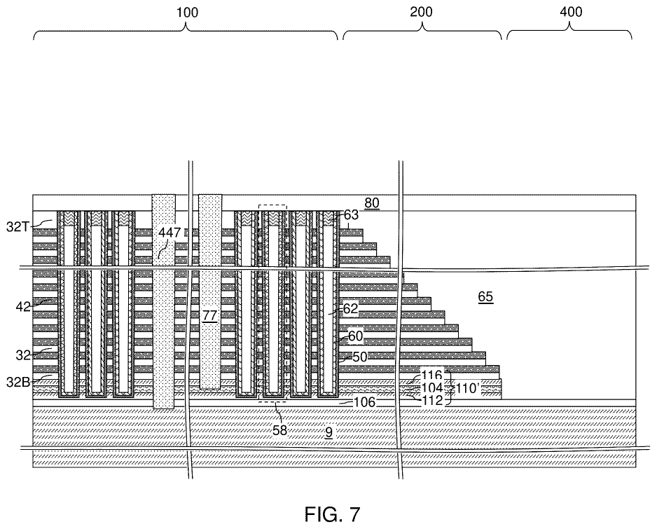

Referring to FIG. 7, a sacrificial fill material can be deposited in the lateral isolation trenches 79 and the through-stack openings 449. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or an organic material. Excess portions of the sacrificial fill material can be removed from above the horizontal plane including the top surface of the contact-level dielectric layer 80. Remaining portions of the sacrificial fill material filling the lateral isolation trenches 79 constitute sacrificial lateral isolation trench fill structures 77. Remaining portions of the sacrificial fill material filling the through-stack openings 449 constitute sacrificial through-stack opening fill structures 447.

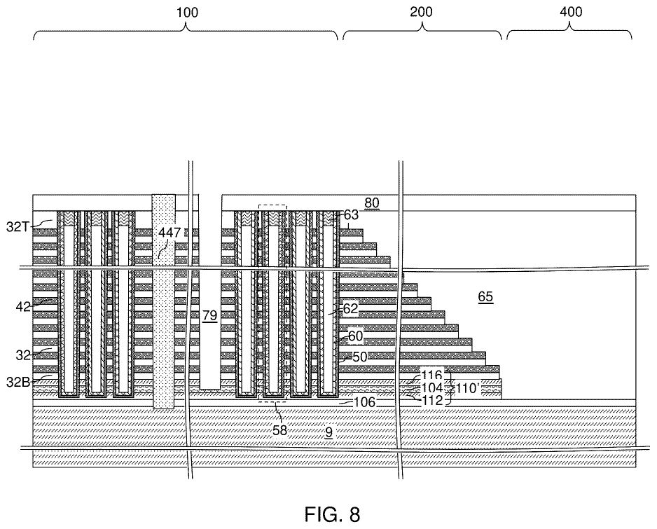

Referring to FIG. 8, a photoresist layer (not shown) can be applied over the contact-level dielectric layer 80, and can be lithographically patterned to cover the sacrificial through-stack opening fill structures 447 without covering the sacrificial lateral isolation trench fill structures 77. The sacrificial lateral isolation trench fill structures 77 can be removed selectively to the materials of the contact-level dielectric layer 80 and the alternating stack (32, 42) to form cavities within the volumes of the lateral isolation trenches 79 (i.e., to reopen the lateral isolation trenches 79).

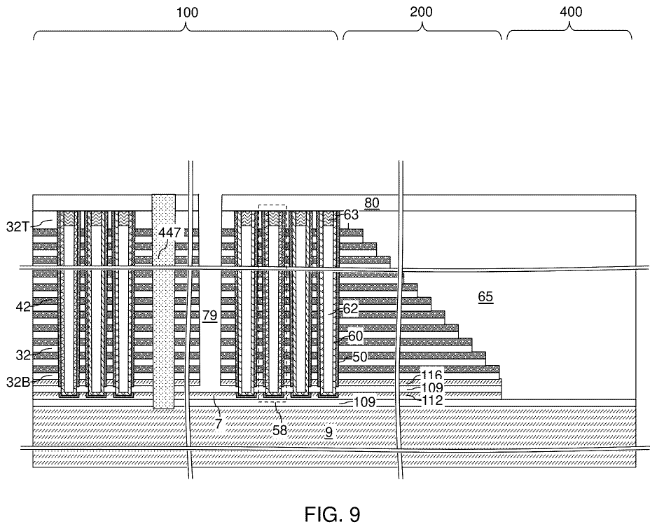

Referring to FIG. 9, an etch-stop spacer (not shown) may be optionally formed on sidewalls of the lateral isolation trenches by depositing and anisotropically etching an etch-stop barrier material, which may comprise silicon oxide or a dielectric metal oxide. An isotropic etch process can be performed to remove the source-level sacrificial layer 104 without removing the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present). For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selectively to the alternating stack (32, 42), the contact-level dielectric layer 80, the retro-stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selectively to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary in-process memory die caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selectively to at least one source-level semiconductor layer (such as the lower source-level semiconductor layer 112 and the upper source-level semiconductor layer 116) and the vertical semiconductor channels 60.

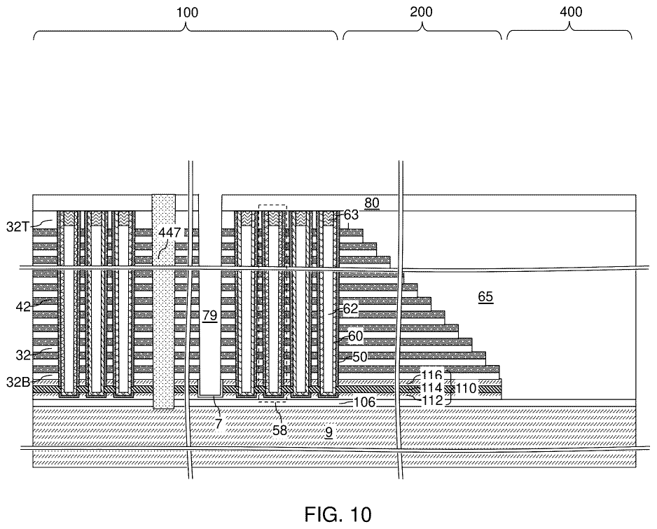

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. Optionally, one or more etch back processes may be used in combination with a plurality of selective or non-selective deposition processes to provide a seamless and/or voidless source contact layer 114. Alternatively, the source contact layer 114 can be formed by performing a non-selective doped semiconductor material deposition process such as a low-pressure chemical vapor deposition process. In this case, an etch-back process can be performed to remove portions of the deposited doped semiconductor material that are deposited in the lateral isolation trenches 79 or above the contact-level dielectric layer 80. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³.

The layer stack including the lower source-level semiconductor layer 112, the source contact layer 114, and the upper source-level semiconductor layer 116 constitutes a source layer 110, which replaces the in-process source-level material layers 110′. The source layer 110 contacts a sidewall surface segment of each of the vertical semiconductor channels 60. An oxidation process can be performed to convert physically exposed portions of the semiconductor material layer around bottom portions of the lateral isolation trenches 79. A semiconductor oxide liner 7, such as a silicon oxide liner, can be formed at the bottom of each lateral isolation trench 79.

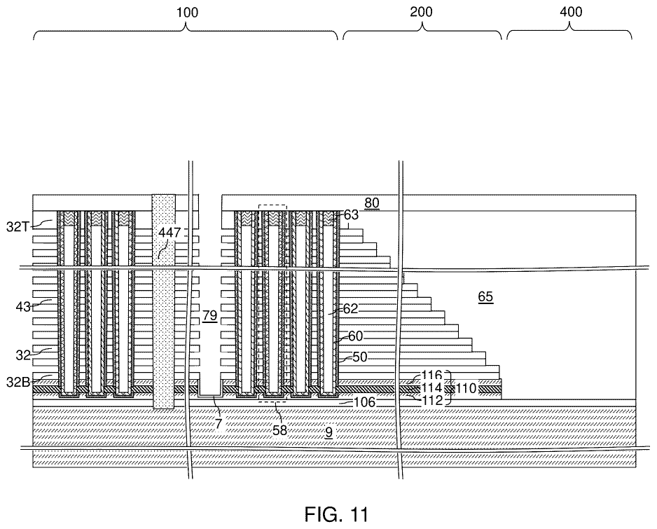

Referring to FIG. 11, an isotropic etch process can be performed to remove the sacrificial material layers 42 selectively to the insulating layers 32, the semiconductor oxide liners 7, the memory opening fill structures 58, and the source layer 110. Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary in-process memory die is immersed in phosphoric acid at or near the boiling point of the phosphoric acid. A suitable clean process may be performed as needed. In summary, the laterally-extending cavities 43 can be formed by removing the sacrificial material layers 42 selectively to the insulating layers 32 and the memory opening fill structures 58.

Referring to FIG. 12, a backside blocking dielectric layer (not shown) may be optionally is deposited in the laterally-extending cavities 43. The backside blocking dielectric layer, if employed, includes, and/or consists essentially of, a dielectric metal oxide material. At least one metallic material can be conformally deposited in the laterally-extending cavities 43. The at least one metallic material may comprise a combination of a metallic nitride barrier material and a metallic fill material. For example, the metallic nitride barrier material may comprise TiN, TaN, WN, or MoN, and the metallic fill material may comprise W, Ru, Mo, Co, etc.

An anisotropic etch process can be performed to remove portions of the at least one metallic material and optionally the backside blocking dielectric layer from inside the volumes of the lateral isolation trenches 79 and from above the contact-level dielectric layer 80. Each contiguous remaining portion of the at least one metallic material located within a volume of a respective laterally-extending cavity 43 constitutes an electrically conductive layer 46. Alternating stacks (32, 46) of insulating layers 32 and electrically conductive layers 46 is formed between each neighboring pair of lateral isolation trenches 79. Thus, the alternating stacks (32, 46) of insulating layers 32 and electrically conductive layers 46 can be laterally spaced apart from each other along the second horizontal direction hd2 by the lateral isolation trenches 79.

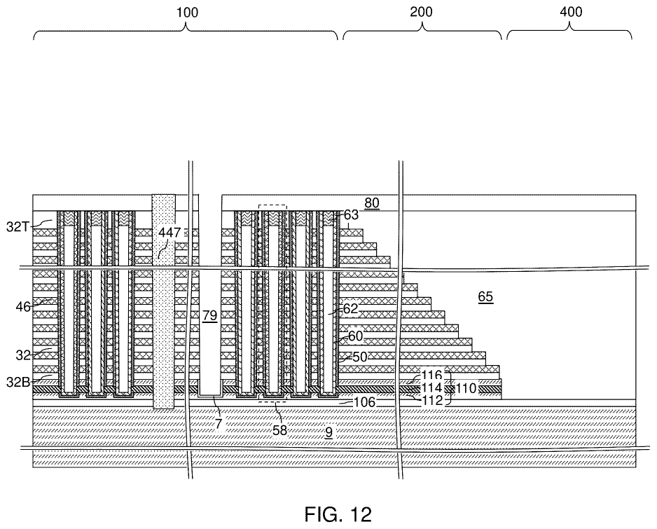

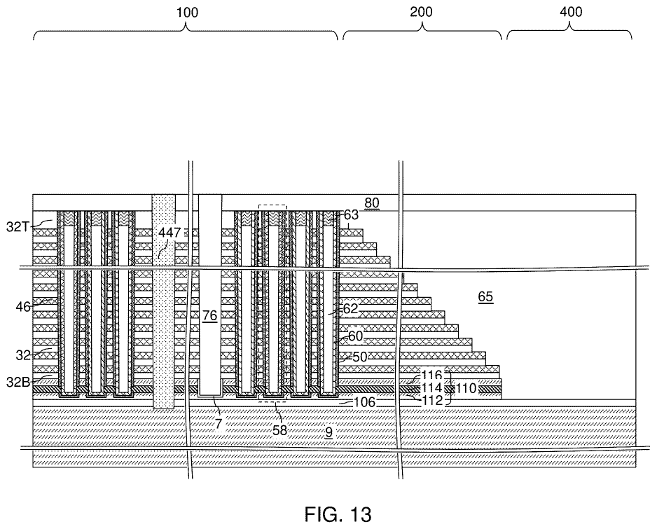

Referring to FIG. 13, an insulating fill material may be conformally deposited in the lateral isolation trenches 79. Excess portions of the insulating fill material may be removed from above the contact-level dielectric layer 80, for example, by a recess etch process.

Each remaining portion of the insulating fill material that fills a respective lateral isolation trench 79 constitutes a lateral isolation trench fill structure 76. Alternatively, each lateral isolation trench fill structure 76 may comprise a combination of a tubular insulating spacer (not expressly shown) and a conductive connection via structure (not expressly shown) that is laterally surrounded by the tubular insulating spacer.

In summary, a lateral isolation trench fill structure 76 having insulating sidewalls can be formed within each lateral isolation trench 79. Each lateral isolation trench fill structure 76 vertically extends from a bottommost surface of an alternating stack (32, 46) to another horizontal plane including a topmost surface of the alternating stack (32, 46).

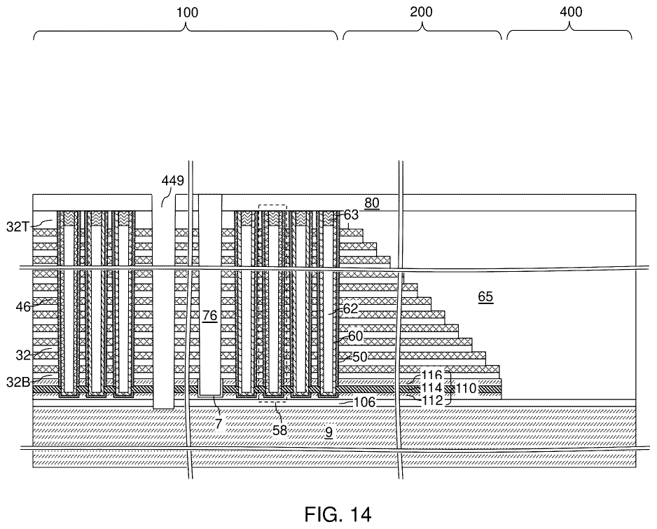

Referring to FIG. 14, a selective etch process can be performed to remove the sacrificial through-stack opening fill structures 447 selectively to the materials of the contact-level dielectric layer 80 and the alternating stacks (32, 42). Cavities are formed in the volumes of the through-stack openings 449.

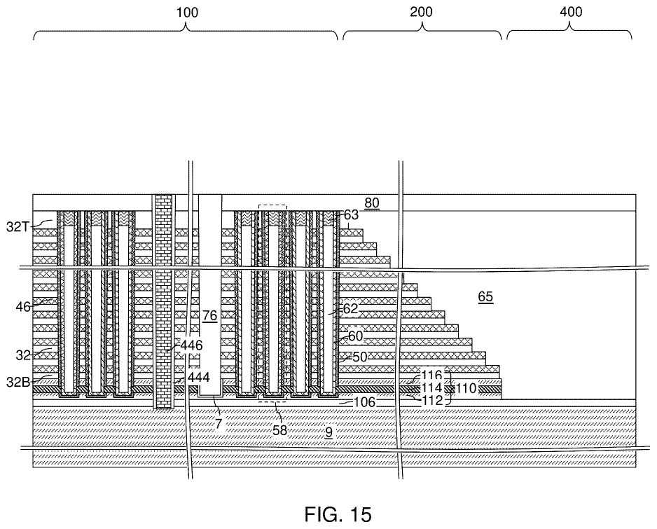

Referring to FIG. 15, a dielectric material, such as silicon oxide, can be conformally deposited in peripheral portions of the through-stack openings 449. An anisotropic etch process can be performed to remove horizontally-extending portions of the deposited dielectric material. Each remaining tubular portion of the deposited dielectric material located in peripheral regions of the through-stack openings 449 constitutes a tubular dielectric spacer 444. The lateral thickness of each tubular dielectric spacer 444 (as measured between an inner sidewall and an outer sidewall) may be in a range from 30 nm to 100 nm, although lesser and greater thicknesses may also be employed.

At least one conductive material, such as at least one metallic material, can be deposited in center regions of the through-stack openings 449. Excess portions of the at least one conductive material can be removed from above the horizontal plane including the top surface of the contact-level dielectric layer 80 by performing a planarization process such as a chemical mechanical planarization process. Each remaining portion of the at least one conductive material that remains in a respective through-stack opening 449 comprises a through-stack via structure 446.

The through-stack via structures 446 are formed in a center region of the in-process memory die. As used herein, the center region is defined as a volume within the in-process memory die that is more proximal to the geometrical center GC of the in-process memory die than to a periphery of the in-process memory die. The periphery is defined by the outer boundary of the in-process memory die in a plan view along a vertical direction.

In one embodiment, at least one of the vertically-extending openings 449 in the alternating stacks (32, 46) is entirely laterally surrounded by a respective one of the alternating stacks (32, 46). In one embodiment, the entirety of at least one of the vertically-extending openings 449 may be located within the area of a respective one of the alternating stacks (32, 46) in the plan view. In one embodiment, at least one of the through-stack via structures 446 is located within a respective one of the vertically-extending openings 449, and is laterally spaced from a sidewall of the respective one of the vertically-extending opening 449 by a respective tubular dielectric spacer 444.

In one embodiment, sidewalls of the through-stack openings 449 may be tapered such that each through-stack opening 449 has a greater lateral dimension at its top than at its bottom. In one embodiment, sidewalls of the through-stack via structures 446 are tapered relative to a vertical direction such that each of the through-stack via structures 446 has a respective variable horizontal cross-sectional area that increases with a vertical distance from the carrier substrate 9.

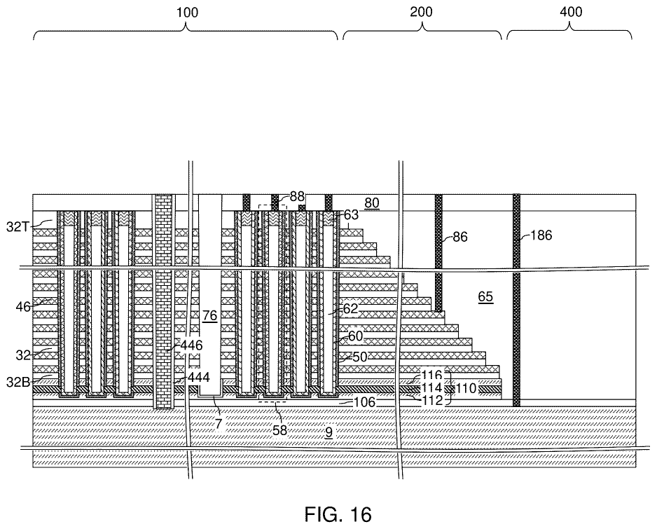

Referring to FIG. 16, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via cavities can be formed through the contact-level dielectric layer 80 and the retro-stepped dielectric material portion 65 on a top surface of a respective one of the electrically conductive layers 46. Peripheral edge seal cavities and peripheral connection via cavities can be formed in the peripheral region 400. The photoresist layer can be subsequently removed, for example, by ashing.

At least one conductive material, such as a combination of a metallic barrier material and a metal fill material, can be deposited in the drain contact via cavities, the layer contact via cavities, and peripheral connection via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46. Remaining portions of the at least one conductive material that fill the respective peripheral connection via cavities constitute peripheral connection via structures 186.

Referring to FIG. 17, additional dielectric material layers embedding interconnect structures can be formed over the contact-level dielectric layer 80. The interconnect structures may comprise an electrically conductive material, such as a metal, a metal alloy, a metal silicide, or a conductive metal nitride. The additional dielectric material layers are herein referred to as memory-die front dielectric material layers 160. The interconnect structures are herein referred to as memory-die interconnect structures (98, 108, 180). The memory-die interconnect structures (98, 108, 180) may include bit lines 108 that laterally extend along the second horizontal direction hd2, bit-line-connection via structures 98 that connect the drain contact via structures 88 with the bit lines 108, and additional interconnect structures 180 which include various types of metal via structures and various types of metal lines.

Memory-die front bonding structures 198 configured for metal-to-metal bonding can be formed in the topmost dielectric layer of the memory-die front dielectric material layers 160. Metal-to-metal bonding involves direct attachment of contacting metal surfaces to each other without use of any intermediate material. As used herein, “metal-to-metal bonding” refers to the process of directly joining metal surfaces without any intervening adhesive or bonding layer. An exemplary metal-to-metal bonding process comprises a copper-to-copper bonding in which mating copper surfaces are pushed against each other at an elevated temperature, which may be in a range from 200 degrees Celsius to 400 degrees Celsius. In one embodiment, the memory-die front bonding structures 198 may have physically exposed copper surfaces.

The exemplary in-process memory die formation is completed to form a memory die 900, i.e., the final device structure derived from the exemplary in-process memory die. In one embodiment, a two-dimensional array of memory dies 900 may be formed on the same carrier substrate 9. For example, the carrier substrate 9 may comprise a commercially available silicon wafer, and the two-dimensional array of memory dies 900 may comprise a periodic rectangular array of memory dies 900 comprising a respective portion of the silicon wafer and the overlying device layers.

In summary, a plurality of memory dies 900 can be provided. Each of the plurality of memory dies 900 may comprise: an alternating stack (32, 46) of insulating layers 32 and electrically conductive layers 46 that alternate along a vertical direction; a two-dimensional array of memory stack structures 55 each containing a respective vertical semiconductor channel 60 and respective vertical stack of memory elements (comprising portions of the memory material layer 54); and through-stack via structures 446 vertically extending at least from a horizontal plane including a bottommost surface of the alternating stack (32, 46) to another horizontal plane including a topmost surface of the alternating stack (32, 46).

Referring to FIG. 18, an exemplary memory-controller die (e.g., logic die) 700 is illustrated. The exemplary memory-controller die 700 may be provided within a unit area in a substrate, such as a semiconductor (e.g., silicon) wafer including a two-dimensional array of memory-controller dies 700. The exemplary memory-controller die 700 comprises a substrate, such as a semiconductor substrate 709, which is also referred to as a controller-die semiconductor substrate. The semiconductor substrate 709 may comprise a portion of a silicon wafer. Shallow trench isolation structures 712 can be formed in an upper portion of the semiconductor substrate 709. A memory controller circuit 720, which is also referred to as a peripheral circuit or driver circuit, can be formed on and/or over the top surface of the semiconductor substrate 709.

The memory controller circuit 720 is configured to control operation of the memory array within the memory die 900. For example, the memory controller circuit 720 may comprise word line drivers configured to drive word lines, which are a subset of the electrically conductive layers 46 within the alternating stacks (32, 46). The memory controller circuit 720 may comprise bit line drivers configured to drive the bit lines 108 in the memory die 900. For example, as described with reference to the memory die 900, the bit lines 108 of a memory die 900 may be electrically connected to first ends (i.e., the ends that are connected to the drain regions 63) of a respective subset of the memory stack structures 55. The memory controller circuit 720 may comprise source line drivers configured to drive one or more source layers to be subsequently formed on the memory die 900 after removal of the carrier substrate 9. The memory controller circuit 720 may also comprise input/output control circuits configured to receive input data from, or to transmit output data to, at least one conductive pad (which may be a bonding structure) to be subsequently formed on the through-stack via structures 446 after removal of the carrier substrate 9. Generally, the memory controller circuit 720 may comprise any electronic circuit configured to manage data flow, handle read and write operations, ensure data integrity through error correction, perform wear leveling to extend memory lifespan, and/or support communication protocols for interfacing with external devices and systems for the three-dimensional memory array in the memory die 900.

Controller-die front interconnect structures 780 embedded within controller-die front dielectric material layers 760 can be formed over the memory controller circuit 720. Specifically, a first subset of the controller-die front interconnect structures 780 embedded within a first subset of the controller-die front dielectric material layers 760 can be formed. The first subset of the controller-die front dielectric material layers 760 is herein referred to as lower controller-die front dielectric material layers 760L. In the illustrated example in FIG. 18, the lower controller-die front dielectric material layers 760L comprise four via-level dielectric material layers and four line-level dielectric material layers. Generally, the total number of line levels within the lower controller-die front dielectric material layers 760L may be in a range from 1 to 12.

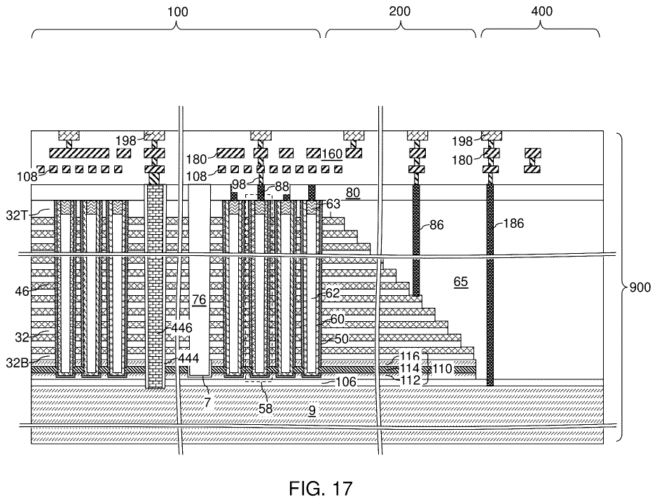

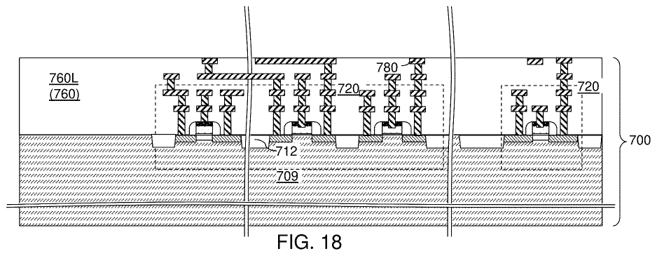

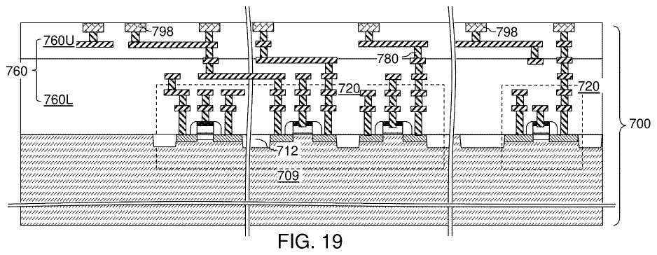

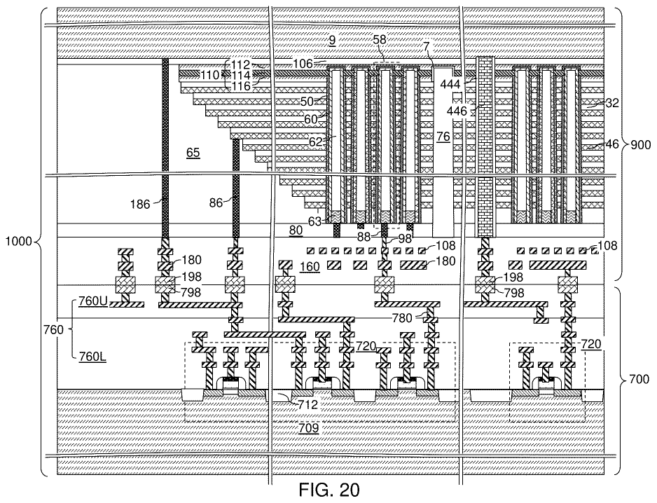

Referring to FIG. 19, a second subset of the controller-die front interconnect structures 780 embedded within a second subset of the controller-die front dielectric material layers 760 can be formed. The second subset of the controller-die front dielectric material layers 760 is herein referred to as upper controller-die front dielectric material layers 760U. In the illustrated example in FIG. 20, the upper controller-die front dielectric material layers 760U comprise a via-level dielectric material layer and two line-level dielectric material layers. Generally, the total number of line levels within the upper controller-die front dielectric material layers 760U may be in a range from 1 to 12.

Bonding structures configured for metal-to-metal bonding can be formed in the topmost layer among the controller-die front dielectric material layers 760. These bonding structures are herein referred to as controller-die front bonding structures 798. The controller-die front bonding structures 798 can be electrically connected to a respective electrical node of the memory controller circuit 720, and can be arranged in a pattern that is a mirror image pattern of the memory-die front bonding structures 198 of the memory die 900. In one embodiment, each memory-controller die 700 may be provided within a unit die area in a semiconductor wafer including a two-dimensional array of memory-controller dies 700.

A plurality of memory-controller dies 700 may be provided. Each memory-controller die 700 comprises a respective semiconductor substrate 709, a respective memory controller circuit 720 including a respective set of semiconductor devices located on a front surface of the respective semiconductor substrate 709; respective controller-die front dielectric material layers 760 embedding respective controller-die front interconnect structures 780 and located on the respective set of semiconductor devices; respective controller-die front bonding structures 798 that are embedded within the controller-die front dielectric material layers 760; and respective TSV structures 716 that vertically extend through a subset of the respective controller-die front dielectric material layers 760 and an upper portion of the respective semiconductor substrate 709.

Referring to FIG. 20, a unit bonded assembly 1000 can be formed by bonding the memory-controller die 700 described with reference to FIG. 20 with the memory die 900 described with reference to FIG. 17. A plurality of unit bonded assemblies 1000 can be formed. Each of the plurality of unit bonded assemblies 1000 constitutes a bonded assembly 1000. The memory-controller die 700 can be attached to the memory die 900 by bonding the controller-die front bonding structures 798 to the memory-die front bonding structures 198. The bonding between mating pairs of a respective memory die 900 and a respective memory-controller die 700 may be performed employing a wafer-to-wafer bonding process in which a two-dimensional array of memory dies 900 is bonded to a two-dimensional array of memory-controller dies 700, by a die-to-wafer bonding process (in which a diced die is bonded to a wafer), or by a die-to-die bonding process (in which two diced dies are bonded to each other). The controller-die front bonding structures 798 within each memory-controller die 700 can be bonded to the memory-die front bonding structures 198 within a respective memory die 900 by metal-to-metal bonding, such as copper-to-copper bonding.

The memory die 900 comprises alternating stacks (32, 46) of insulating layers 32 and electrically conductive layers 46 and memory-die front dielectric material layers 160 embedding memory-die interconnect structures (180, 108, 98) and memory-die front bonding structures 198. Memory stack structures 55 vertically extend through a respective one of the alternating stacks (32, 46) in a memory array region 100, and layer contact via structures 86 contact a respective electrically conductive layer 46 within the alternating stacks (32, 46) in a contact region 200. In one embodiment, through-stack via structures 446 vertically extend through vertically-extending openings 449 in the alternating stacks (32, 46) within a center region of the memory die 900, which is defined as a volume within the memory die 900 that is more proximal to a geometrical center GC of the memory die 900 than to a periphery of the memory die 900 defined by outer sidewalls of the memory die 900 in a plan view along a vertical direction. A memory-controller die 700 comprises a memory controller circuit 720 including a control circuitry for controlling operation of the electrically conductive layers 46 and further comprises controller-die front dielectric material layers 760 embedding controller-die front interconnect structures 780 and controller-die front bonding structures 798. The controller-die front bonding structures 798 are bonded to the memory-die front bonding structures 198.

Within each bonded assembly 1000 (i.e., a unit bonded assembly 1000) of a respective memory die 900 and a respective memory-controller die 700, the respective memory die 900 comprises respective memory-die front bonding structures 198 embedded within respective memory-die front dielectric material layers 160, and the respective memory-controller die 700 comprises respective controller-die front bonding structures 798 embedded within respective controller-die front dielectric material layers 760 and bonded to the respective memory-die front bonding structures 198. In one embodiment, the respective controller-die front bonding structures 798 are bonded to the respective memory-die front bonding structures 198 via metal-to-metal bonding, such as copper-to-copper bonding.

In one embodiment, dielectric-to-dielectric bonding, such as silicon oxide-to-silicon oxide bonding may be employed in conjunction with the metal-to-metal bonding. In this case, a topmost memory-die front dielectric material layer of the respective memory-die front dielectric material layers 160 is bonded to a topmost controller-die front dielectric material layer among the controller-die front dielectric material layers 760 via dielectric-to-dielectric bonding (i.e., hybrid bonding is used to bond the respective memory die to the respective memory-controller die).

In one embodiment, the respective memory die 900 includes a respective three-dimensional array of memory elements (e.g., flash memory cells comprising as portions of a memory material layer 54), and the respective memory-controller die 700 includes a respective memory controller circuit 720 configured to control operation of the respective three-dimensional array of memory elements. In one embodiment, a subset of the through-stack via structures 446 is electrically connected to a subset of semiconductor devices (e.g., input/output control devices, such as field effect transistors) in the respective memory controller circuit 720 of the memory-controller die 700 through a subset of the memory-die interconnect structures (180, 108, 98) and through a subset of the controller-die front interconnect structures 780.

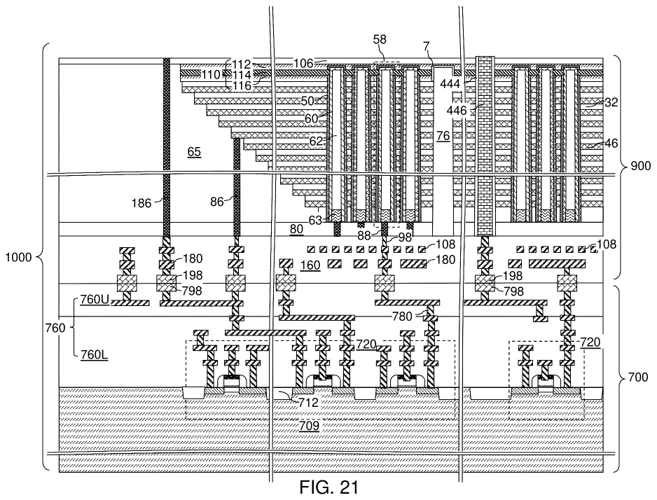

Referring to FIG. 21, the carrier substrate 9 may be removed, for example, by grinding, polishing, cleaving, an isotropic etch process, and/or an anisotropic etch process. If a polishing process such as a chemical mechanical polishing process is employed to remove the carrier substrate 9, the first memory-die proximal dielectric material layer 106 may be subsequently employed as a polishing stopper material layer. If an etch process such as a wet etch process is employed to remove the carrier substrate 9, the first memory-die proximal dielectric material layer 106 may be subsequently employed as an etch stop material layer. End surfaces of the through-stack via structures 446 may be physically exposed upon removal of the carrier substrate 9.

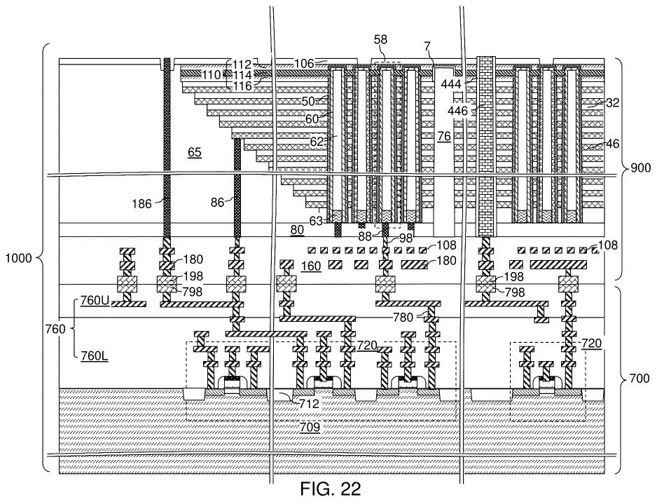

Referring to FIG. 22, backside via openings can be formed through the first memory-die proximal dielectric material layer 106 on the backside surface (i.e., a distal surface) of the source layer 110 by performing a combination of a lithographic patterning process and an anisotropic etch process. Additional backside via openings can be formed through the first memory-die proximal dielectric material layer 106 and through the source layer 110 over the end portions of the peripheral connection via structures 186 by performing a combination of an additional lithographic patterning process and an additional anisotropic etch process.

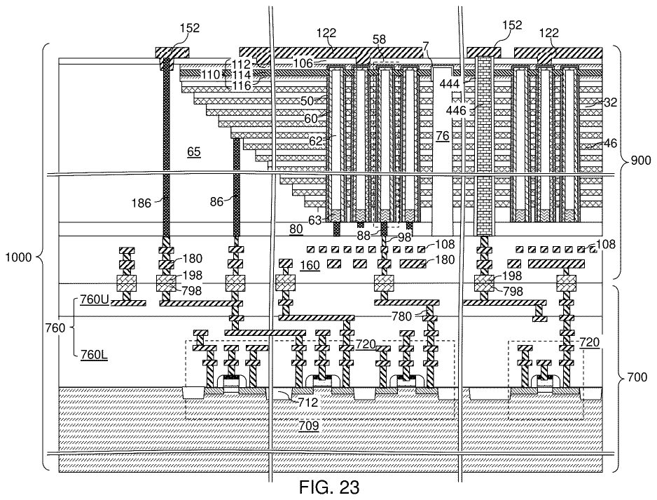

Referring to FIG. 23, at least one electrically conductive material can be deposited in the openings, over the distal surface of the first memory-die proximal dielectric material layer 106, and over end portions of the memory stack structures 55 that are distal from an interface between the memory die 900 and the memory-controller die 700 to form a backside conductive layer. The at least one electrically conductive material may comprise a combination of a metallic barrier material (such as TiN, TaN, WN, and/or MoN) and an aluminum-based material comprising aluminum at an atomic percentage greater than 90 %. The backside conductive layer can be subsequently patterned to form various proximal memory-die interconnect structures (122, 152) that are composed primarily of aluminum.

In one embodiment, the proximal memory-die interconnect structures (122, 152) may comprise at least one source connection structure 122 and memory-die backside pad structures 152. In one embodiment, the memory-die backside pad structures 152 may comprise aluminum pad structures 152. Each of the at least one source connection structure 122 may be electrically connected to a respective source line driver through a respective metal via structure 186 vertically extending through the retro-stepped dielectric material portion 65, a respective subset of the memory-die interconnect structures 180, a respected bonded pair of a controller-die front bonding structure 798 and a memory-die front bonding structure 198, and a respective subset of the controller-die front interconnect structures 780. Each source connection structure 122 is electrically connected to the end portions of a respective subset of the memory stack structures 55 (e.g., to source side end portions of the vertical semiconductor channels 60). Each of the peripheral connection via structures 186 may be physically and/or electrically connected to a respective one of the memory-die backside pad structures 152 or the source connection structure 122. Each of the through-stack via structures 446 may be physically and/or electrically connected to a respective one of the memory-die backside pad structures 152 or the source connection structure 122.

At least a subset of the memory-die backside pad structures 152 can be electrically connected to a respective electrical node of the memory controller circuit 720 through a respective peripheral connection via structure 186, a respective subset of the memory-die interconnect structures 180, a respected bonded pair of a controller-die front bonding structure 798 and a memory-die front bonding structure 198, and a respective subset of the controller-die front interconnect structures 780. Optionally, an additional subset of the memory-die backside pad structures 152 can be electrically connected to a respective electrical node of the memory controller circuit 720 through a respective through-stack via structure 446, a respective subset of the memory-die interconnect structures 180, a respected bonded pair of a controller-die front bonding structure 798 and a memory-die front bonding structure 198, and a respective subset of the controller-die front interconnect structures 780.

In some embodiments, wafer-level die sorting (D/S) may be performed using one or more of the memory-die backside pad structures 152. In this case, an electrical probe is contacted to one or more of the memory-die backside pad structure to conduct electrical testing of one or more of the memory die 900 of the bonded assembly 1000. Since the aluminum material of the memory-die backside pad structure is harder than copper material of the bonding pads, no damage or a reduced amount of damage is caused by the D/S testing than if the electrical probe is contacted to a relatively soft copper bonding pad. Thus, the number of probe marks left by the testing process is reduced or the probe marks are eliminated.

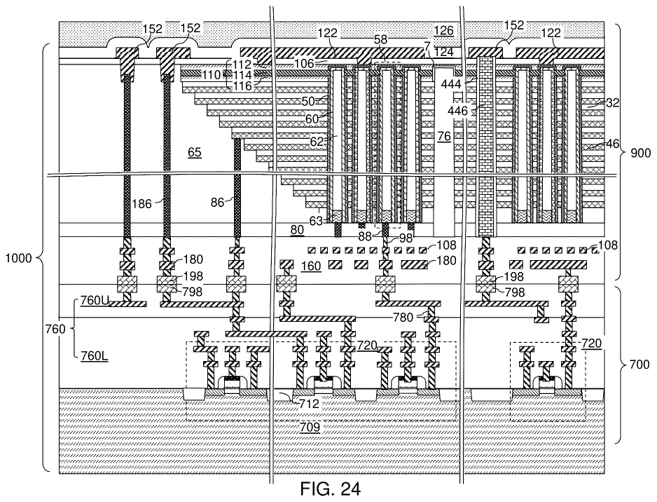

Referring to FIG. 24, after the D/S testing, at least one second memory-die proximal dielectric material layer 124 can be formed over the at least one source connection structure 122 and the memory-die backside pad structures 152. The at least one second memory-die proximal dielectric material layer 124 comprises at least one dielectric material layer. For example, the at least one second memory-die proximal dielectric material layer 124 may comprise a stack of a stack of a first silicon oxide passivation layer, a silicon nitride passivation layer, and a third silicon oxide passivation layer. Generally, any combination of one or more inorganic interlayer dielectric (ILD) material layers may be employed for the at least one second memory-die proximal dielectric material layer 124. In one embodiment, the entirety of the first memory-die proximal dielectric material layer 106 and the at least one second memory-die proximal dielectric material layer 124 may consist essentially of dielectric material materials, such as silicon oxide, silicon nitride, silicon oxynitride, silicon carbonitride, and/or at least one dielectric metal oxide. The proximal memory-die interconnect structures (122, 152) can be embedded within the memory-die proximal dielectric material layers (106, 124).

A bonding-level dielectric layer 126 can be formed over the memory-die proximal dielectric material layers (106, 124). The bonding-level dielectric layer 126 comprises a dielectric material that can provide dielectric-to-dielectric bonding with another dielectric material layer in another semiconductor die. For example, the bonding-level dielectric layer 126 may comprise undoped silicate glass (i.e., silicon oxide), a doped silicate glass, silicon nitride, silicon carbonitride, or an organic dielectric material. The top surface of the bonding-level dielectric layer 126 may be planar, i.e., may be formed within a horizontal plane.

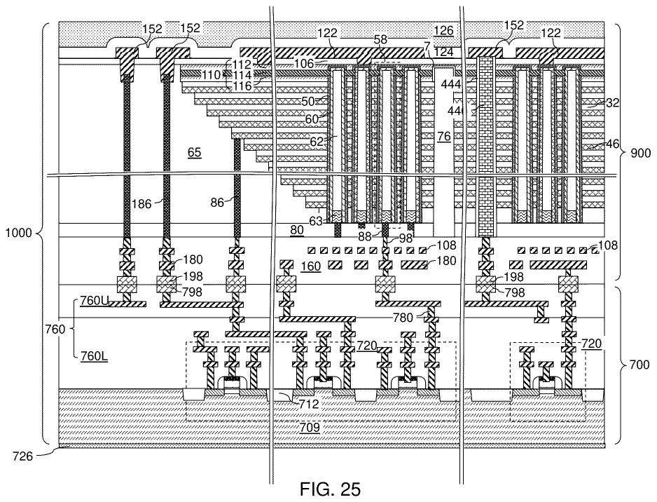

Referring to FIG. 25, the controller-die semiconductor substrate 709 may be thinned from the backside, for example, by grinding, polishing, at least one anisotropic etch process, and/or at least one isotropic etch process. The thickness of the controller-die semiconductor substrate 709 after thinning may be in a range from 100 nm to 10 microns, although lesser or greater thicknesses may also be employed.

An optional backside bonding-level dielectric layer 726 may be formed over the thinned backside surface of the controller-die semiconductor substrate 709. The backside bonding-level dielectric layer 726 may have the same or different composition as that of the bonding-level dielectric layer 126. For example, the backside bonding-level dielectric layer 726 may comprise undoped silicate glass (i.e., silicon oxide), a doped silicate glass, silicon nitride, silicon carbonitride, or an organic dielectric material. The top surface of the backside bonding-level dielectric layer 726 may be planar, i.e., may be formed within a horizontal plane.

Referring to FIG. 26, a first exemplary structure according to an embodiment of the present disclosure is illustrated, which can be formed by providing a first bonded assembly 1001 and a second bonded assembly 1002, and by bonding the first bonded assembly 1001 and the second bonded assembly 1002 at a first bonding interface 1010. Each of the first bonded assembly 1001 and the second bonded assembly 1002 can be provided within a respective wafer, and a wafer-to-wafer bonding may be performed to form a two-dimensional array of composite dies (1001, 1002) that includes a vertical stack of a respective first bonded assembly 1001 and a respective second bonded assembly 1002. The wafer including a two-dimensional array of first bonded assemblies 1001 may be provided by performing a sequence of processing steps described with reference to FIG. 1-25. Likewise, the wafer including a two-dimensional array of second bonded assemblies 1001 may be provided by performing a sequence of processing steps described with reference to FIG. 1-25.

The first bonded assembly 1001 and the second bonded assembly 1002 in a composite die (1001, 1002) are collectively referred to as bonded assemblies 1000. For each composite die including a vertically bonded pair of a first bonded assembly 1001 and a second bonded assembly 1002, the first bonded assembly 1001 comprises a first memory die 900 and a first memory-controller die 700 which is bonded (e.g., copper-to-copper pad bonded) to the first memory die 900. The first memory die 900 includes a first alternating stack (32, 46) of first insulating layers 32 and first electrically conductive layers 46 and first memory stack structures 55 vertically extending through the first alternating stack (32, 46) and comprising a three-dimensional array of first memory elements (which may comprise portions of memory material layers 54). The first memory-controller die 700 includes a first memory controller circuit 720 configured to control operation of the three-dimensional array of first memory elements.

Further, for each composite die including a vertically bonded pair of a first bonded assembly 1001 and a second bonded assembly 1002, the second bonded assembly 1002 includes a second memory die 900 and a second memory-controller die 700 that is bonded (e.g., copper-to-copper pad bonded) to the second memory die 900. The second memory die 900 includes a second alternating stack (32, 46) of second insulating layers 32 and second electrically conductive layers 46 and second memory stack structures 55 vertically extending through the second alternating stack (32, 46) and comprising a three-dimensional array of second memory elements (which may comprise portions of memory material layers 54). The second memory-controller die 700 includes a second memory controller circuit 720 configured to control operation of the three-dimensional array of second memory elements.

The second bonded assembly 1002 is bonded to the first bonded assembly 1001 by performing a fusion bonding, which may comprise dielectric-to-semiconductor bonding, or by performing a dielectric-to-dielectric bonding. For example, if the controller-die semiconductor substrate 709 of the second bonded assembly 1002 comprises silicon, the bonding-level dielectric layer 126 of the first memory die 900 can comprise a silicon oxide, silicon nitride, silicon carbonitride or polymer material that bonds with silicon of the controller-die semiconductor substrate 709.

Alternatively, the optional backside bonding-level dielectric layer 726 including a silicon oxide, silicon nitride, silicon carbonitride or polymer material can be deposited on the physically exposed surface of the controller-die semiconductor substrate 709, and dielectric-to-dielectric bonding can be performed between the backside bonding-level dielectric layer 726 and the bonding-level dielectric layer 126 of the first memory die 900. Layer 726 is shown in dashed lines to indicate that it may be either present or omitted at the first (e.g., fusion) bonding interface 1010.

In one embodiment, the pattern of interconnect structures in the first bonded assembly 1001 and the pattern of interconnect structures in the second bonded assembly 1002 may be different. Specifically, the first bonded assembly 1001 may comprise an area that is free of any interconnect structure and has an areal overlap with a respective one of the interconnect structures in the second bonded assembly 1002. The respective one of the interconnect structures in the second bonded assembly 102 may be located within the second memory-controller die 700 or within the second memory die 900.

Referring to FIG. 27, a photoresist layer 435 can be applied on a physically exposed horizontal surface of the first bonded assembly 1001. The physically exposed horizontal surface may be the horizontal surface of the first bonded assembly 1001 that is most distal from the first bonding interface 1010 between the first bonded assembly 1001 and the second bonded assembly 1002 (e.g., the backside of the substrate 709 of the first bonded assembly 1001). The photoresist layer 435 can be lithographically patterned to form openings in areas that are free of semiconductor devices in the memory controller circuits 720 in the first memory-controller die 700 and the second memory-controller die 700, and are free of any alternating stack (32, 46) in the first memory die 900. The areas of the openings in the photoresist layer 435 can be selected such that a first subset of the openings in the photoresist layer 435 has an areal overlap with a subset of the interconnect structures in the second bonded assembly 1002, and a second subset of the openings in the photoresist layer 435 has an areal overlap with a subset of the interconnect structures in the first bonded assembly 1001.

An anisotropic etch process can be performed to transfer the patten of the openings in the photoresist layer 435 through underlying material portions. The anisotropic etch process may comprise a plurality of anisotropic etch steps that sequentially etch through the various material layers within the composite die (1001, 1002) selectively to the conductive materials of the interconnect structures within the composite die (1001, 1002). For example, the plurality of anisotropic etch steps may comprise a first anisotropic etch step that etches unmasked portions of the controller-die semiconductor substrate 709 in the first bonded assembly 1001, a second anisotropic etch step that etches unmasked portions of the various dielectric materials within the first bonded assembly 1001 selectively to the materials of the interconnect structures in the first bonded assembly 1001, a third anisotropic etch step that etches unmasked portions of the controller-die semiconductor substrate 709 in the second bonded assembly 1002 selectively to the materials of the interconnect structures in the first bonded assembly 1001, and a fourth anisotropic etch step that etches unmasked portions of the various dielectric materials within the second bonded assembly 1002 selectively to the materials of the interconnect structures in the second bonded assembly 1002 and the materials of the interconnect structures in the first bonded assembly 1001.

Contact via cavities (457, 455) are formed in the volumes from which the materials of the composite die (1001, 1002) are removed by the anisotropic etch process. The contact via cavities (457, 455) comprise first through-die contact via cavities 457 and intra-die contact via cavities 455. Each first through-die contact via cavity 457 continuously extends through the entire thickness of the first memory die 900 and the first memory-controller die 700 of the first bonded assembly 1001, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory-controller die 700. For example, the respective one of interconnect structures within the second bonded assembly 1002 may be a respective one of the controller-die front interconnect structures 780 or a respective one of the controller-die front bonding structures 798 in the second memory-controller die 700.

Each intra-die contact via cavity 455 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the controller-die front interconnect structures 780 or a respective one of the controller-die front bonding structures 798 in the first memory-controller die 700. The photoresist layer 453 may be subsequently removed, for example, by ashing.

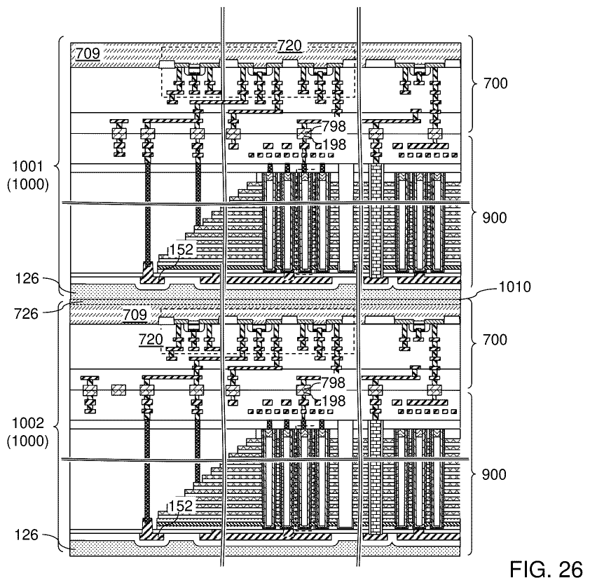

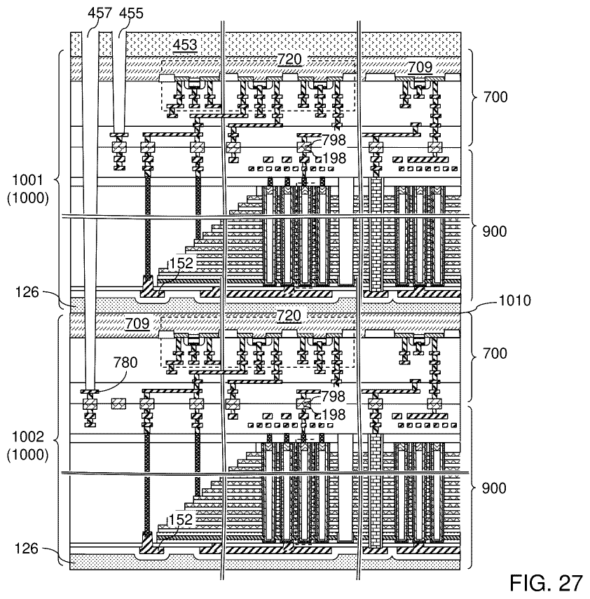

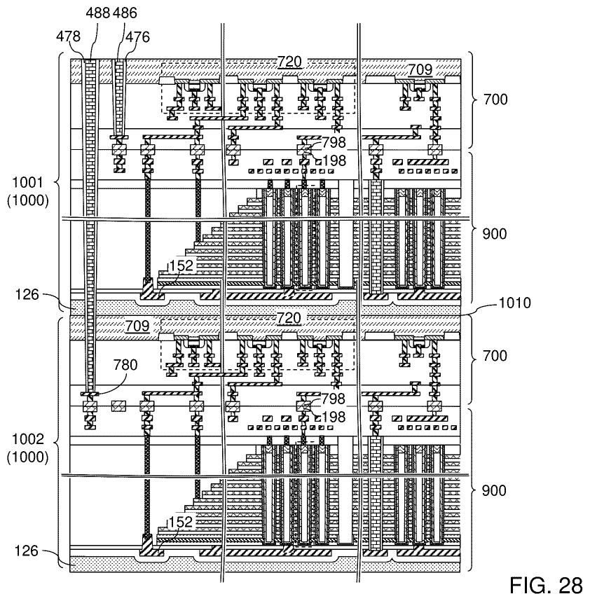

Referring to FIG. 28, a continuous insulating liner may be conformally deposited in peripheral portions of the contact via cavities (457, 455) and over the distal horizontal surface of the first bonded assembly 1001. The continuous insulating liner comprises an insulating material such as silicon oxide, silicon nitride, silicon carbonitride, or a combination thereof. The thickness of the continuous insulating liner at the bottom of the contact via cavities (457, 455) may be in a range from 10 nm to 500 nm, although lesser or greater thicknesses may also be employed.

An anisotropic etch process can be performed to remove horizontally-extending portions of the continuous insulating liner. Remaining tubular portions of the continuous insulating liner located in peripheral regions of the contact via cavities (457, 455) constitute insulating spacers (478, 476). The insulating spacers (478, 476) comprise first through-die insulating spacers 478 that are formed within the first through-die contact via cavities 457 and intra-die insulating spacers 476 that are formed within the intra-die contact via cavities 455. Each of the insulating spacers (478, 476) may have a tubular configuration, and thus, may be topologically homeomorphic to a torus, i.e., may be continuously stretched without forming a new hole and without eliminating any existing hole into the shape of a torus.

Each first through-die insulating spacer 478 continuously extends through the entire thickness of the first memory die 900 and the first memory-controller die 700 of the first bonded assembly 1001, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory-controller die 700. For example, the respective one of interconnect structures within the second bonded assembly 1002 may be a respective one of the controller-die front interconnect structures 780 or a respective one of the controller-die front bonding structures 798 in the second memory-controller die 700.

Each intra-die insulating spacer 476 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900 of the first bonded assembly. For example, the respective one of interconnect structures within the first bonded assembly 1001 may be a respective one of the controller-die front interconnect structures 780 or a respective one of the controller-die front bonding structures 798 in the first memory-controller die 700.

At least one electrically conductive material can be conformally deposited in the remaining unfilled volumes of the contact via cavities (457, 455) and over the distal horizontal surface of the first bonded assembly 1001. The at least one electrically conductive material may comprise a combination of a metallic barrier liner material (such as TiN, TaN, WN, and/or MoN) and a metal fill material (such as Cu, Al, W, Mo, Co, Ru, etc.). Excess portions of the at least one electrically conductive material can be removed from above the horizontal plane including the distal horizontal surface of the first bonded assembly 1001 by performing a planarization process, such as a chemical mechanical polishing process. Remaining portions of the at least one electrically conductive material located within a respective one of the first through-die contact via cavities 457 constitute first through-die contact via structures 488. Remaining portions of the at least one electrically conductive material located within a respective one of the intra-die contact via cavities 455 constitute intra-die contact via structures 486.

In one embodiment, the first memory-controller die 700 comprises a first controller-die semiconductor substrate 709, each of the first through-die contact via structures 488 is laterally spaced from the first controller-die semiconductor substrate 709 by a respective first through-die insulating spacer 478, and each of the intra-die contact via structures 486 is laterally spaced from the first controller-die semiconductor substrate 709 by a respective intra-die insulating spacer 476.

In one embodiment, each first through-die insulating spacer 478 comprises a respective first annular end surface contacting a respective one of the interconnect structures within the second bonded assembly 1002, and further comprises a respective second annular end surface located within a same horizontal plane as an end surface of a respective first through-die contact via structure 488 that is laterally surrounded by the first through-die insulating spacer 478. The end surfaces of the first through-die contact via structure 488 can be located on an opposite side of the first bonding interface 1010 with respect to the first bonded assembly 1001.

In one embodiment, each intra-die insulating spacer 476 comprises a respective first annular end surface contacting a respective one of the interconnect structures within the first bonded assembly 1001, and further comprises a respective second annular end surface located within a same horizontal plane as an end surface of a respective intra-die contact via structure 486 that is laterally surrounded by the intra-die insulating spacer 476. The end surfaces of the intra-die contact via structure 486 can be located on an opposite side of the first bonding interface 1010 with respect to the first bonded assembly 1001.

Each first through-die contact via structure 488 continuously extends through the entire thickness of the first memory die 900 and the first memory-controller die 700 of the first bonded assembly 1001, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory-controller die 700. For example, the respective one of interconnect structures within the second bonded assembly 1002 may be a respective one of the controller-die front interconnect structures 780 or a respective one of the controller-die front bonding structures 798 in the second memory-controller die 700.

Each intra-die contact via structure 486 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the controller-die front interconnect structures 780 or a respective one of the controller-die front bonding structures 798 in the first memory-controller die 700.

In one embodiment, one or more of the interconnect structures in the second bonded assembly 1002 that are contacted by the first through-die contact via structures 488 are located within the second memory-controller die 700. In one embodiment, the second memory-controller die 700 is bonded to the first bonded assembly 1001 at the first bonding interface 1010. In one embodiment, the first memory die 900 is bonded to the second bonded assembly 1002 at the first bonding interface 1010. In one embodiment, the first memory die 900 is bonded to the second memory-controller die 700 at the first bonding interface 1010.

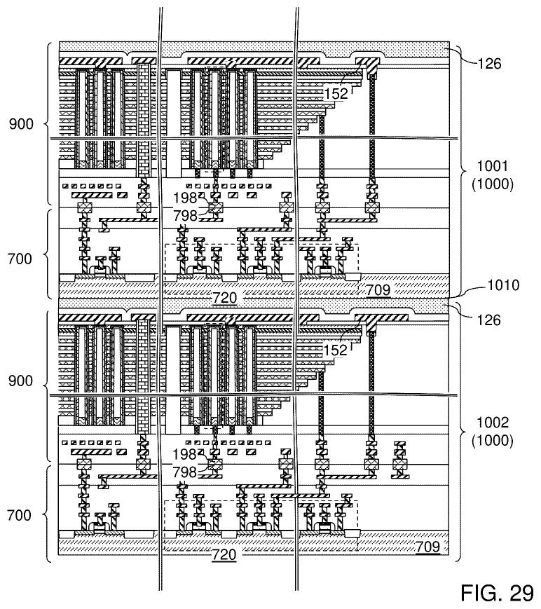

Referring to FIG. 29, a second exemplary structure is illustrated. The second exemplary structure includes a composite die (1001, 1002) containing two bonded assemblies of a respective memory die 900 and a respective memory-controller die 700.

In the second exemplary structure illustrated in FIG. 29, the first memory-controller die 700 in the first bonded assembly 1001 can be bonded to the memory die 900 in the second bonded assembly 1002 by dielectric-to-semiconductor bonding or by dielectric-to-dielectric bonding, as described above. In the second exemplary structure, the pattern of interconnect structures in the first bonded assembly 1001 and the pattern of interconnect structures in the second bonded assembly 1002 may be different. Specifically, the first bonded assembly 1001 may comprise an area that is free of any interconnect structure and has an areal overlap with a respective one of the interconnect structures in the second bonded assembly 1002. The respective one of the interconnect structures in the second bonded assembly 102 may be located within the second memory-controller die 700 or within the second memory die 900.

In the illustrative example, the first bonded assembly 1001 comprises an area that is free of any interconnect structure and has an areal overlap with a respective one of the memory-die backside pad structures 152. Generally, the interconnect structures in the second bonded assembly 1002 that does not have any areal overlap with the interconnect structures in the first bonded assembly 1001 may comprise a subset of the interconnect structures in the second memory die 900 and/or a subset of the interconnect structures in the second memory-controller die 700.

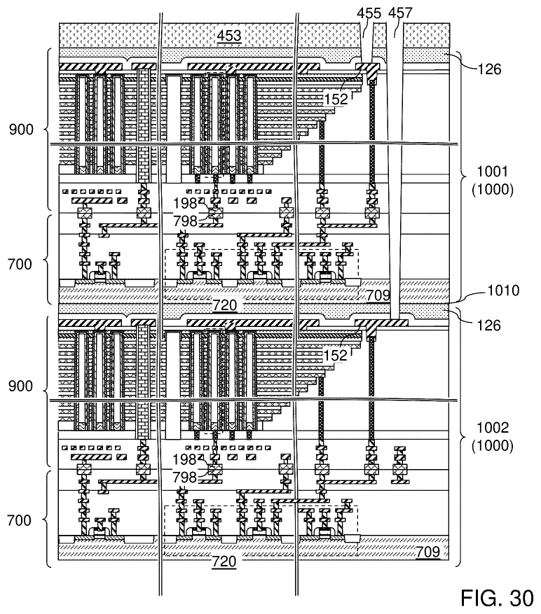

Referring to FIG. 30, a photoresist layer 435 can be applied on a physically exposed horizontal surface of the first bonded assembly 1001. The physically exposed horizontal surface may be the horizontal surface of the first bonded assembly 1001 that is most distal from the first bonding interface 1010 between the first bonded assembly 1001 and the second bonded assembly 1002. The physically exposed horizontal surface may be a horizontal (e.g., top horizontal) surface of the first memory die 900 (e.g., top surface of layer 126). The photoresist layer 435 can be lithographically patterned to form openings in areas that are free of semiconductor devices in the memory controller circuits 720 in the first memory-controller die 700 and the second memory-controller die 700, and are free of any alternating stack (32, 46) in the first memory die 900. The areas of the openings in the photoresist layer 435 can be selected such that a first subset of the openings in the photoresist layer 435 has an areal overlap with a subset of the interconnect structures in the second bonded assembly 1002, and a second subset of the openings in the photoresist layer 435 has an areal overlap with a subset of the interconnect structures in the first bonded assembly 1001.

An anisotropic etch process can be performed to transfer the patten of the openings in the photoresist layer 435 through underlying material portions. The anisotropic etch process may comprise a plurality of anisotropic etch steps that sequentially etch through the various material layers within the composite die (1001, 1002) selectively to the metallic materials of the interconnect structures within the composite die (1001, 1002). For example, the plurality of anisotropic etch steps may comprise a first anisotropic etch step that etches unmasked portions of the various dielectric materials within the first bonded assembly 1001 selectively to the materials of the interconnect structures in the first bonded assembly 1001, a second anisotropic etch step that etches unmasked portions of the controller-die semiconductor substrate 709 in the second bonded assembly 1002 selectively to the materials of the interconnect structures in the first bonded assembly 1001, and a third anisotropic etch step that etches unmasked portions of the various dielectric materials within the second bonded assembly 1002 selectively to the materials of the interconnect structures in the second bonded assembly 1002 and the materials of the interconnect structures in the first bonded assembly 1001.

Contact via cavities (457, 455) are formed in the volumes from which the materials of the composite die (1001, 1002) are removed by the anisotropic etch process. The contact via cavities (457, 455) comprise first through-die contact via cavities 457 and intra-die contact via cavities 455. Each first through-die contact via cavity 457 continuously extends through the entire thickness of the first memory die 900 and the first memory-controller die 700 of the first bonded assembly 1001, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of the memory-die backside pad structures 152.

Each intra-die contact via cavity 455 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the memory-die backside pad structures 152 in the first memory die 900. The photoresist layer 453 may be subsequently removed, for example, by ashing.

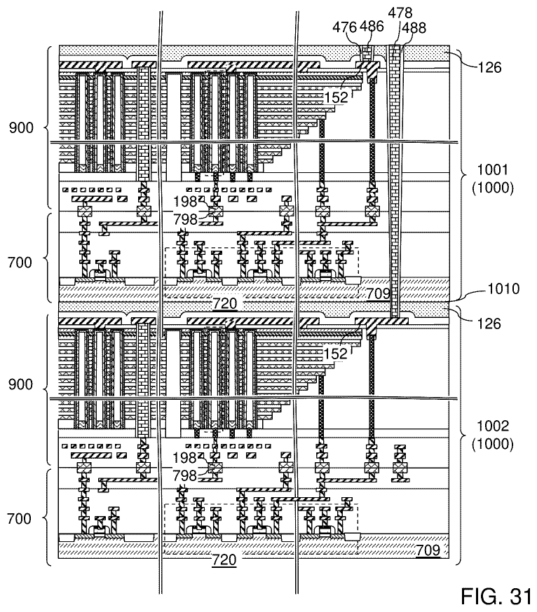

Referring to FIG. 31, the processing steps described with reference to FIG. 28 may be performed to form the insulating spacers (478, 476) and the contact via structures (488, 486). The insulating spacers (478, 476) comprise first through-die insulating spacers 478 that are formed within the first through-die contact via cavities 457 and intra-die insulating spacers 476 that are formed within the intra-die contact via cavities 455. Each of the insulating spacers (478, 476) may have a tubular configuration.

Each first through-die insulating spacer 478 continuously extends through the entire thickness of the first memory die 900 and the first memory-controller die 700 of the first bonded assembly 1001, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory die 900. For example, the respective one of interconnect structures within the second bonded assembly 1002 may be a respective one of the memory-die backside pad structures 152 of the second memory die 900.

Each intra-die insulating spacer 476 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the memory-die backside pad structures 152 of the first memory die 900.

In one embodiment, the first memory-controller die 700 comprises a first controller-die semiconductor substrate 709, each of the first through-die contact via structures 488 is laterally spaced from the first controller-die semiconductor substrate 709 by a respective first through-die insulating spacer 478.

In one embodiment, each first through-die insulating spacer 478 comprises a respective first annular end surface contacting a respective one of the interconnect structures within the second bonded assembly 1002, and further comprises a respective second annular end surface located within a same horizontal plane as an end surface of a respective first through-die contact via structure 488 that is laterally surrounded by the first through-die insulating spacer 478. The end surfaces of the first through-die contact via structure 488 can be located on an opposite side of the first bonding interface with respect to the first bonded assembly 1001. In one embodiment, each intra-die insulating spacer 476 comprises a respective first annular end surface contacting a respective one of the interconnect structures within the first bonded assembly 1001, and further comprises a respective second annular end surface located within a same horizontal plane as an end surface of a respective intra-die contact via structure 486 that is laterally surrounded by the intra-die insulating spacer 476. The end surfaces of the intra-die contact via structure 486 can be located on an opposite side of the first bonding interface with respect to the first bonded assembly 1001.

Each first through-die contact via structure 488 continuously extends through the entire thickness of the first memory die 900 and the first memory-controller die 700 of the first bonded assembly, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory-controller die 700. For example, the respective one of interconnect structures within the second bonded assembly 1002 may be a respective one of the memory-die backside pad structures 152 of the second memory die 900.

Each intra-die contact via structure 486 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the memory-die backside pad structures 152 in the first memory-controller die 700.

In one embodiment, one or more of the interconnect structures in the second bonded assembly 1002 that are contacted by the first through-die contact via structures 488 are located within the second memory die 900. In one embodiment, the second memory die 900 is bonded to the first bonded assembly 1001 at the first bonding interface 1010. In one embodiment, the first memory-controller die 900 is bonded to the second bonded assembly 1002 at the first bonding interface 1010. In one embodiment, the second memory die 900 is bonded to the first memory-controller die 700 at the first bonding interface 1010.

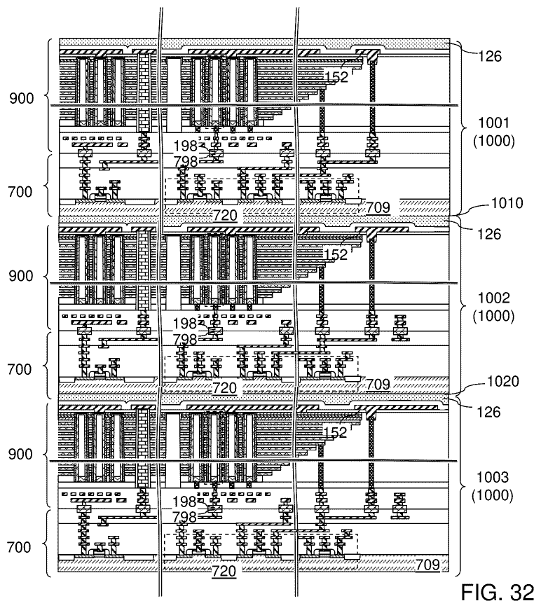

Referring to FIG. 32, a third exemplary structure according to an embodiment of the present disclosure is illustrated. The third exemplary structure comprises a composite die (1001, 1002, 1003) containing three bonded assemblies of a respective memory die 900 and a respective memory-controller die 700.

The third bonded assembly 1003 includes a third memory die 900 and a third memory-controller die 700. The third memory die 900 includes a third alternating stack (32, 46) of third insulating layers 32 and third electrically conductive layers 46 and third memory stack structures 55 vertically extending through the third alternating stack (32, 46) and comprising a three-dimensional array of third memory elements. The third memory-controller die 700 includes a third memory controller circuit 720 configured to control operation of the three-dimensional array of third memory elements.

Generally, the third bonded assembly 1003 may be provided by performing processing steps described with reference to FIG. 1-25. In one embodiment, an array of third bonded assemblies 1003 may be provided within a wafer. The third bonded assembly 1003 can be bonded to the second bonded assembly 1002. Generally, any bonding method that may be employed for bonding a second bonded assembly 1002 to a first bonded assembly 1001 (or for bonding a two-dimensional array of second bonded assemblies 1002 in a wafer to a two-dimensional array of first bonded assemblies 1001 in another wafer) may be employed to bond the third bonded assembly 1003 to the second bonded assembly 1002. The third bonded assembly 1003 contacts the second bonded assembly 1002 at a second bonding interface.

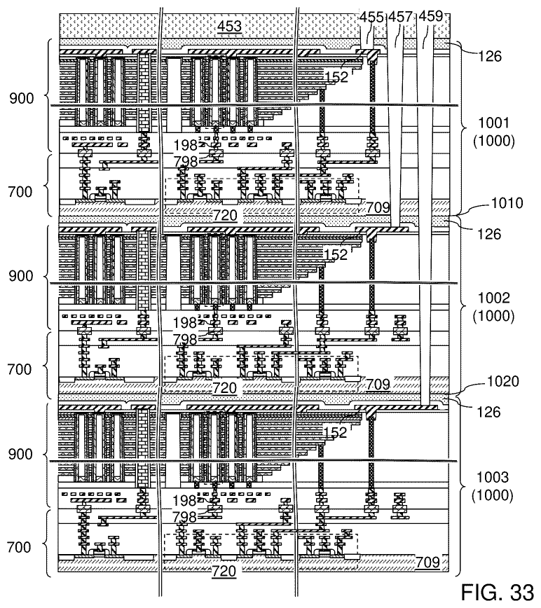

Referring to FIG. 33, a photoresist layer 435 can be applied on a physically exposed horizontal surface of the first bonded assembly 1001. The physically exposed horizontal surface may be the horizontal surface of the first bonded assembly 1001 that is most distal from the first bonding interface between the first bonded assembly 1001 and the second bonded assembly 1002. The physically exposed horizontal surface may be a horizontal surface of the first memory die 900. The photoresist layer 435 can be lithographically patterned to form various openings.

The openings in the photoresist layer 435 can be formed in areas that are free of semiconductor devices in the memory controller circuits 720 in the first memory-controller die 700 and the second memory-controller die 700, and are free of any alternating stack (32, 46) in the first memory die 900. In one embodiment, the areas of a first subset of the openings in the photoresist layer 435 has an areal overlap with a subset of the interconnect structures in the second bonded assembly 1002; the areas of a second subset of the openings in the photoresist layer 435 has an areal overlap with a subset of the interconnect structures in the first bonded assembly 1001; and the areas of a third subset of the openings in the photoresist layer 435 has an real overlap with a subset of the interconnect structures in the third bonded assembly 1003.

An anisotropic etch process can be performed to transfer the patten of the openings in the photoresist layer 435 through underlying material portions. The anisotropic etch process may comprise a plurality of anisotropic etch steps that sequentially etch through the various material layers within the composite die (1001, 1002, 1003) selectively to the metallic materials of the interconnect structures within the composite die (1001, 1002, 1003). For example, the plurality of anisotropic etch steps may comprise a first anisotropic etch step that etches unmasked portions of the various dielectric materials within the first bonded assembly 1001 selectively to the materials of the interconnect structures in the first bonded assembly 1001 and the semiconductor material of the controller-die semiconductor substrate 709 in the first bonded assembly 1001; a second anisotropic etch step that etches unmasked portions of the controller-die semiconductor substrate 709 in the first bonded assembly 1001 selectively to the materials of the interconnect structures in the first bonded assembly 1001; a third anisotropic etch step that etches unmasked portions the various dielectric materials within the second bonded assembly 1002 selectively to the materials of the interconnect structures in the first bonded assembly 1001, the materials of the interconnect structures in the second bonded assembly 1002, and the semiconductor material of the controller-die semiconductor substrate 709 in the second bonded assembly 1001; a fourth anisotropic etch step that etches unmasked portions of the controller-die semiconductor substrate 709 in the second bonded assembly 1001 selectively to the materials of the interconnect structures in the first bonded assembly 1001 and the materials of the interconnect structures in the second bonded assembly; and a fifth anisotropic etch step that etches unmasked portions of the various dielectric materials within the third bonded assembly 1003 selectively to the materials of the interconnect structures in the first bonded assembly 1001, the materials of the interconnect structures in the second bonded assembly 1002, and the materials of the interconnect structures in the third bonded assembly 1003.

Contact via cavities (457, 455, 459) are formed in the volumes from which the materials of the composite die (1001, 1002, 1003) are removed by the anisotropic etch process. The contact via cavities (457, 455, 459) comprise first through-die contact via cavities 457, intra-die contact via cavities 455, and second through-die contact via cavities 459.

Each first through-die contact via cavity 457 continuously extends through the entire thickness of the first memory die 900 and the first memory-controller die 700 of the first bonded assembly, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of the memory-die backside pad structures 152.

Each intra-die contact via cavity 455 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the memory-die backside pad structures 152 in the first memory die 900. The photoresist layer 453 may be subsequently removed, for example, by ashing.

Each second through-die contact via cavity 459 continuously extends through the entire thickness of the first memory die 900 and the first memory-controller die 700 of the first bonded assembly 1001, through the first bonding interface 1010, through the entire thickness of the second memory die 900 and the second memory-controller die 700 of the second bonded assembly 1002, through the second bonding interface 1020, and through at least one dielectric material layer within the third bonded assembly 1003 and down to a top surface of a respective one of interconnect structures within the third bonded assembly 1003. Generally, the respective one of interconnect structures within the third bonded assembly 1003 may be provided within the third memory-controller die 700 or within the third memory die 900. In one embodiment, the respective one of interconnect structures within the third bonded assembly 1002 may be a respective one of the memory-die backside pad structures 152.

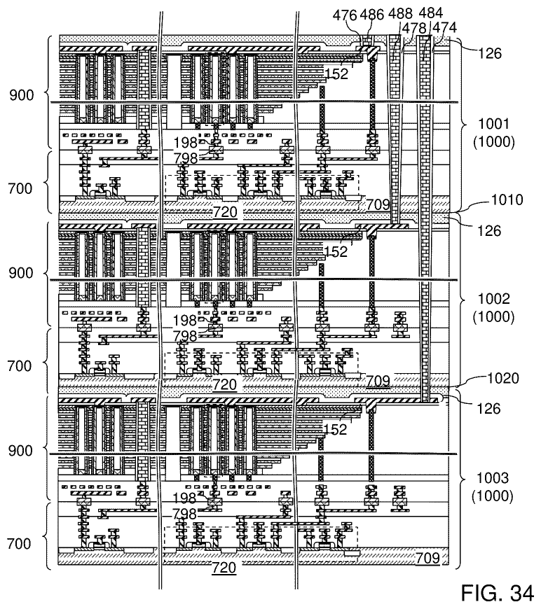

Referring to FIG. 34, the processing steps described with reference to FIG. 28 or FIG. 31 may be performed to form insulating spacers (478, 476, 474) and contact via structures (488, 486, 484). The insulating spacers (478, 476, 474) comprise first through-die insulating spacers 478 that are formed within the first through-die contact via cavities 457, intra-die insulating spacers 476 that are formed within the intra-die contact via cavities 455, and second through-die insulating spacers 474 that are formed within the second through-die contact via cavities 459. Each of the insulating spacers (478, 476, 474) may have a tubular configuration.

Each first through-die insulating spacer 478 continuously extends through the entire thickness of the first memory die 900 and the first memory-controller die 700, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory die 900. For example, the respective one of interconnect structures within the second bonded assembly 1002 may be a respective one of the memory-die backside pad structures 152 of the second memory die 900.

Each intra-die insulating spacer 476 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the memory-die backside pad structures 152 of the first memory die 900.

Each second through-die insulating spacer 474 continuously extends through the entire thickness of the first memory die 900 and the first memory-controller die 700 of the first bonded assembly 1001, through the first bonding interface 1010, through the entire thickness of the second memory die 900 and the second memory-controller die 700 of the second bonded assembly, through the second bonding interface 1020, and through at least one dielectric material layer within the third bonded assembly 1003 and down to a top surface of a respective one of interconnect structures within the third bonded assembly 1003. Generally, the respective one of interconnect structures within the third bonded assembly 1003 may be provided within the third memory-controller die 700 or within the third memory die 900. In one embodiment, the respective one of interconnect structures within the third bonded assembly 1003 may be a respective one of interconnect structures within the third memory die 900. For example, the respective one of interconnect structures within the third bonded assembly 1002 may be a respective one of the memory-die backside pad structures 152 of the third memory die 900.

In one embodiment, the first memory-controller die 700 comprises a first controller-die semiconductor substrate 709, each of the first through-die contact via structures 488 is laterally spaced from the first controller-die semiconductor substrate 709 by a respective first through-die insulating spacer 478, and each of the second through-die contact via structures 484 is laterally spaced from the first controller-die semiconductor substrate 709 and from the second controller-die semiconductor substrate 709 by a respective second through-die insulating spacer 474.

In one embodiment, each first through-die insulating spacer 478 comprises a respective first annular end surface contacting a respective one of the interconnect structures within the second bonded assembly 1002, and further comprises a respective second annular end surface located within a same horizontal plane as an end surface of a respective first through-die contact via structure 488 that is laterally surrounded by the first through-die insulating spacer 478. The end surfaces of the first through-die contact via structure 488 can be located on an opposite side of the first bonding interface with respect to the first bonded assembly 1001. In one embodiment, each intra-die insulating spacer 476 comprises a respective first annular end surface contacting a respective one of the interconnect structures within the first bonded assembly 1001, and further comprises a respective second annular end surface located within a same horizontal plane as an end surface of a respective intra-die contact via structure 486 that is laterally surrounded by the intra-die insulating spacer 476. The end surfaces of the intra-die contact via structure 486 can be located on an opposite side of the first bonding interface with respect to the first bonded assembly 1001. In one embodiment, each second through-die insulating spacer 474 comprises a respective first annular end surface contacting a respective one of the interconnect structures within the third bonded assembly 1003, and further comprises a respective second annular end surface located within a same horizontal plane as an end surface of a respective second through-die contact via structure 484 that is laterally surrounded by the second through-die insulating spacer 474. The end surfaces of the second through-die contact via structure 484 can be located on an opposite side of the first bonding interface with respect to the first bonded assembly 1001.

Each first through-die contact via structure 488 continuously extends through the entire thickness of the first memory die 900 and the first memory-controller die 700 of the first bonded assembly 1001, through the first bonding interface 1010, and through at least one dielectric material layer within the second bonded assembly 1002 and down to a top surface of a respective one of interconnect structures within the second bonded assembly 1002. Generally, the respective one of interconnect structures within the second bonded assembly 1002 may be provided within the second memory-controller die 700 or within the second memory die 900. In one embodiment, the respective one of interconnect structures within the second bonded assembly 1002 may be a respective one of interconnect structures within the second memory-controller die 700. For example, the respective one of interconnect structures within the second bonded assembly 1002 may be a respective one of the memory-die backside pad structures 152 of the second memory die 900.

Each intra-die contact via structure 486 continuously extends from the distal horizontal surface of the first bonded assembly 1001 to a respective one of the interconnect structures in the first bonded assembly 1001. Generally, the respective one of interconnect structures within the first bonded assembly 1001 may be provided within the first memory-controller die 700 or within the first memory die 900. For example, the respective one of interconnect structures within the first bonded assembly 1001 may be a respective one of the memory-die backside pad structures 152 in the first memory-controller die 700.

Each second through-die contact via structure 484 continuously extends through the entire thickness of the first memory die 900 and the first memory-controller die 700 of the first bonded assembly 1001, through the first bonding interface 1010, through the entire thickness of the second memory die 900 and the second memory-controller die 700 of the second bonded assembly 1002, through the second bonding interface 1020, and through at least one dielectric material layer within the third bonded assembly 1003 and down to a top surface of a respective one of interconnect structures within the third bonded assembly 1003. Generally, the respective one of interconnect structures within the third bonded assembly 1003 may be provided within the third memory-controller die 700 or within the third memory die 900. In one embodiment, the respective one of interconnect structures within the third bonded assembly 1003 may be a respective one of interconnect structures within the third memory die 900. For example, the respective one of interconnect structures within the third bonded assembly 1002 may be a respective one of the memory-die backside pad structures 152 of the third memory die 900.

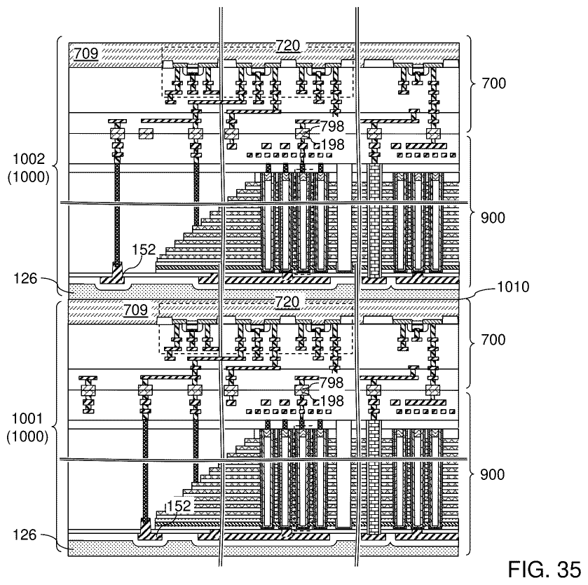

Referring to FIG. 35, a fourth exemplary structure is illustrated. The fourth exemplary structure includes a composite die (1001, 1002) containing two bonded assemblies of a respective memory die 900 and a respective memory-controller die 700.

In the fourth exemplary structure, the through-die contact via structures 488 and additional intra-die via structures 586 are formed from opposite ends of the composite die (1001, 1002). In one embodiment, the through-die contact via structures 488 are from the top side of the first memory die 900 of the first bonded assembly 1001, while the additional intra-die via structures 586 are formed from the bottom side of the second memory-controller die 700 of the second bonded assembly.

Referring to FIG. 36, the processing steps described with reference to FIGS. 30 and 31 can be performed to form first through-die contact via structures 488 and intra-die contact via structures 486. In fourth exemplary structure, additional intra-die via structures vertically extending from a horizontal plane including a distal horizontal surface of the second bonded assembly toward the first bonding interface 1010 can be performed after formation of the first through-die contact via structures 488 and intra-die contact via structures 486, or alternatively, prior to formation of the first through-die contact via structures 488 and intra-die contact via structures 486. To distinguish the first through-die contact via structures 488 and intra-die contact via structures 486 (which vertically extend upward from a horizontal plane including a distal horizontal surface of the first bonded assembly 1001 in FIG. 36) from additional intra-die via structures vertically extending from the horizontal plane including the distal horizontal surface of the second bonded assembly toward the first bonding interface, the first through-die contact via structures 488 and intra-die contact via structures 486 are hereafter referred to as primary-direction contact via structures (488, 486).

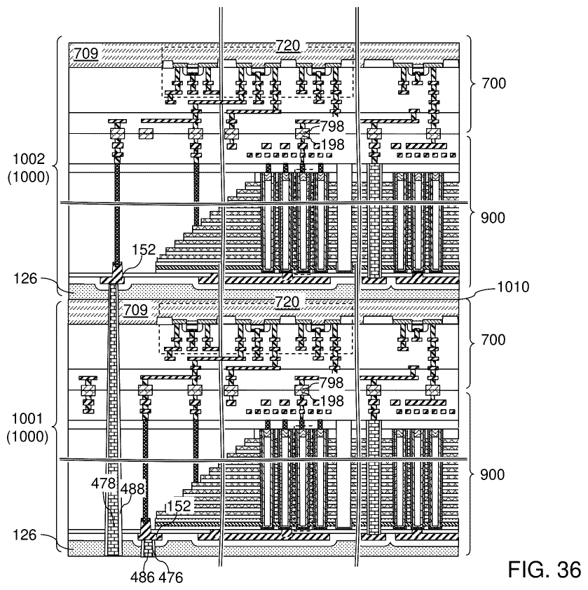

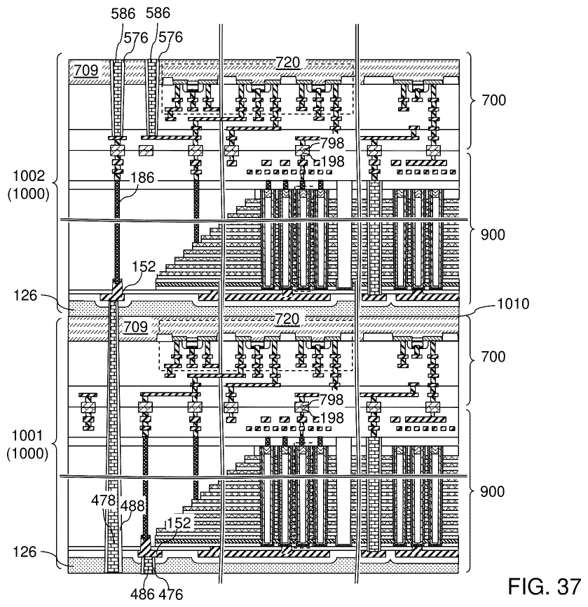

Referring to FIG. 37, the processing steps described with reference to FIGS. 27 and 28 can be performed with any needed changes to form additional intra-die via structures 586 vertically extending from the horizontal plane including the distal horizontal surface of the second bonded assembly toward the first bonding interface. The additional intra-die via structures 586 are herein referred to as counter-direction intra-die contact via structures 586, which are counter-direction contact via structures, i.e., contact via structures vertically extending along the opposite direction of the primary-direction contact via structures (488, 486).

In one embodiment, a contact via structure is formed by filling a contact via cavity, and a lateral dimension of a contact via cavity decreases with an vertical etch distance from the surface from which the contact via cavity is etched. Thus, the lateral dimension of each of the primary-direction contact via structures (488, 486) and the counter-direction intra-die contact via structures 586 is greater within a respective distal horizontal plane from which formation of a corresponding contact via cavity is etched relative to a terminal end of the respective contact via structure that contacts a respective one of the interconnect structures. The direction of each contact via structure can be defined by a vertical arrow pointing from the side with a larger lateral dimension toward the side with a smaller lateral dimension. Thus, the direction of the counter-direction intra-die contact via structures 586 is the opposite of the direction of the primary-direction contact via structures (488, 486).

In other words, the first end of the counter-direction intra-die contact via structures 586 located at a first side of the composite die (1001, 1002) is thicker than the second end of the counter-direction intra-die contact via structures 586 located closer to the first bonding interface 1010 than the first end. In contrast, the first end of the primary-direction contact via structures (488, 486) located at a second side of the composite die (1001, 1002) is thicker than the second end of the primary-direction contact via structures (488, 486) located closer to the first bonding interface 1010 than the first end.

In one embodiment, counter-direction contact via cavities can be formed from the side of the distal horizontal surface of the second bonded assembly 1002 toward the first bonding interface 1010. Thus, the counter-direction contact via cavities vertically extend from the distal horizontal plane of the second bonded assembly 1002 toward the first bonding interface 1010. The distal horizontal plane of the second bonded assembly 1002 includes a horizontal surface of the second bonded assembly 1002 that is most distal from the first bonding interface 1010.

Counter-direction insulating spacers 576 can be formed in peripheral regions of the counter-direction contact via cavities by conformal deposition of a continuous insulating liner and by an anisotropic etch process that removes horizontally-extending portions of the continuous insulating liner. Each counter-direction insulating spacer 576 can be formed within a respective one of the counter-direction contact via cavities, and can have a respective tubular configuration.

At least one electrically conductive material can be deposited in remaining unfilled volumes of the counter-direction contact via cavities and over the distal horizontal surface of the second bonded assembly 1002. Excess portions of the at least one electrically conductive material can be removed from above the horizontal plane including the distal horizontal surface of the second bonded assembly 1002 by performing a planarization process such as a chemical mechanical polishing process. Remaining portions of the at least one electrically conductive material in the counter-direction contact via cavities constitute counter-direction contact via structures 586.

A first subset of the counter-direction contact via structure 586 can be electrically connected to a respective one of the first through-die contact via structures 488. In this case, electrically conductive paths vertically extending from the first distal horizontal plane of the first bonded assembly 1001 to a second distal horizontal plane of the second bonded assembly 1002 may be formed. Each electrically conductive path may comprise a first through-die contact via structure 488, a counter-direction contact via structure 586, and at least two interconnect structures (152, 186) embedded in the second bonded assembly 1002. Each such electrically conductive path vertically extends from the first through-die contact via structure 488 to the counter-direction contact via structure 586. The first through-die contact via structure 488 contacts one of the interconnect structures 152 in the second bonded assembly 1002, and the counter-direction contact via structure 586 contacts another of the interconnect structures 186 in the second bonded assembly 1002. In one embodiment, the counter-direction contact via structure 586 can be located within the second bonded assembly 1002, and can include a respective distal horizontal surface located within the distal horizontal plane of the second bonded assembly 1002 (i.e., a horizontal plane of the second bonded assembly 1002 that is most distal from the first bonding interface 1010).

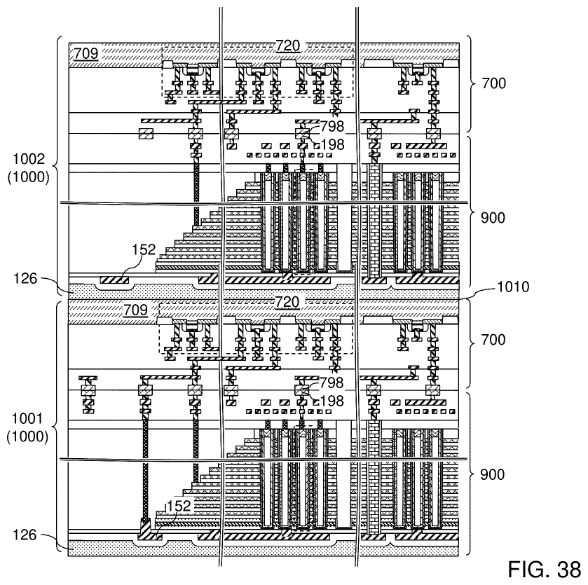

Referring to FIG. 38, a fifth exemplary structure can be derived from the fourth exemplary structure by employing the same interconnect structure 152 in the second bonded assembly to provide direct contact with a first through-die contact via structure 488 and with a counter-direction contact via structure 588. In this embodiment, the electrically conductive path does not include the second interconnect structure 186 of the fourth exemplary structure.

Referring to FIG. 39, the processing steps described with reference to FIG. 36 can be performed to form first through-die contact via structures 488 and intra-die contact via structures 486.

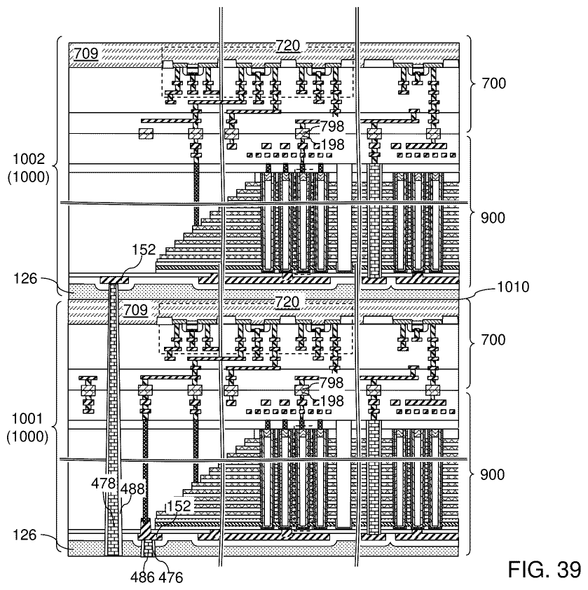

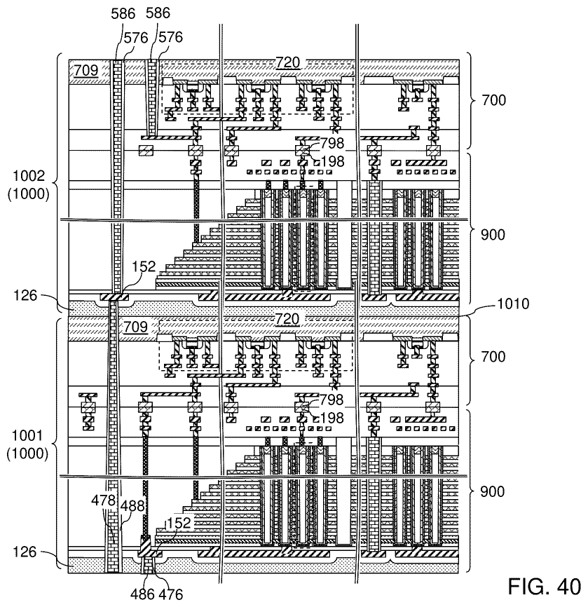

Referring to FIG. 40, the processing steps described with reference to FIG. 37 can be performed to form counter-direction insulating spacers 576 and counter-direction contact via structures 586.

A first subset of the counter-direction contact via structure 586 can be electrically connected to a respective one of the first through-die contact via structures 488. In this case, electrically conductive paths vertically extending from the first distal horizontal plane of the first bonded assembly 1001 to a second distal horizontal plane of the second bonded assembly 1002 may be formed. Each electrically conductive path may comprise and/or may consist of a first through-die contact via structure 488, a counter-direction contact via structure 586, and an interconnect structure 152 embedded in the second bonded assembly 1002. Each such electrically conductive path vertically extends from the first through-die contact via structure 488 to the counter-direction contact via structure 586. The first through-die contact via structure 488 contacts one of the interconnect structures 152 in the second bonded assembly 1002, and the counter-direction contact via structure 586 contacts the same interconnect structure 152 in the second bonded assembly 1002 from the opposite side. In one embodiment, the counter-direction contact via structure 586 can be located within the second bonded assembly 1002, and can include a respective distal horizontal surface located within the distal horizontal plane of the second bonded assembly 1002 (i.e., a horizontal plane of the second bonded assembly 1002 that is most distal from the first bonding interface 1010).

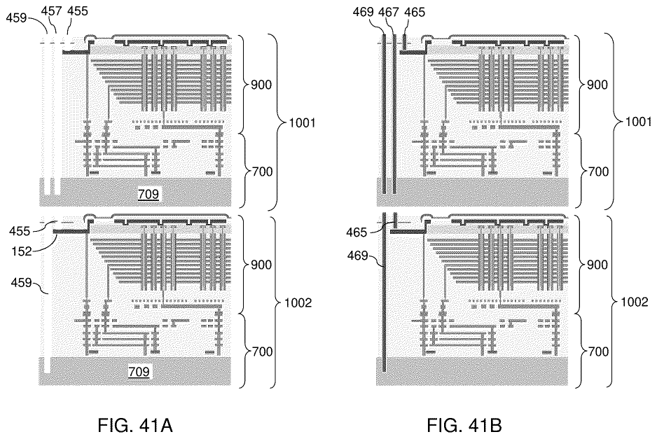

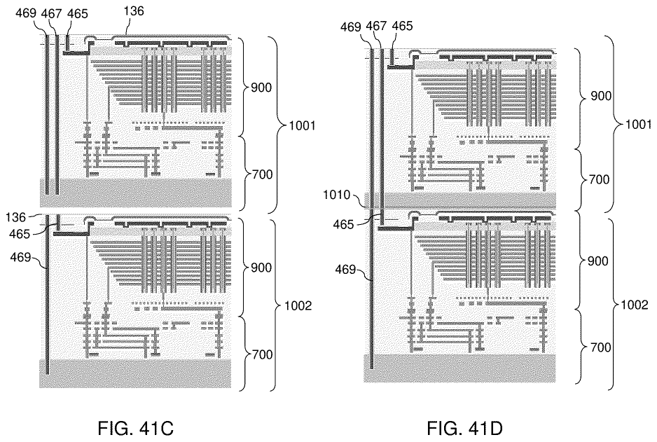

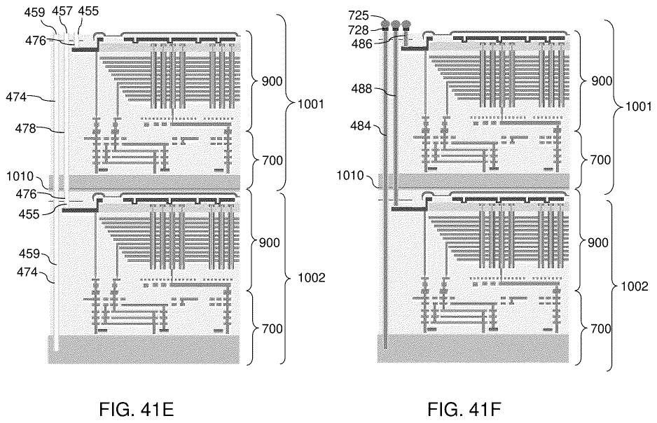

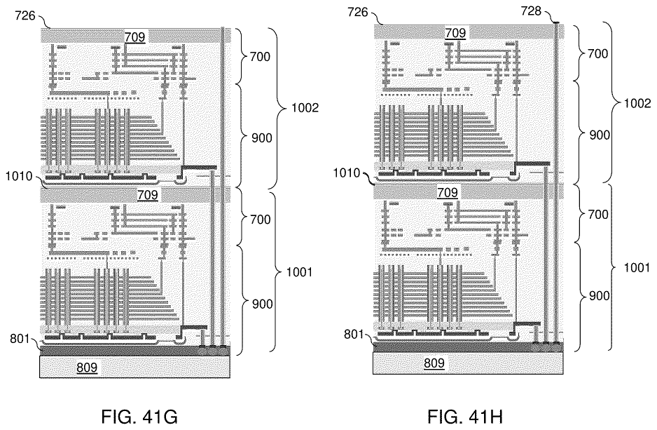

FIG. 41A-41H are vertical cross-sectional views of steps of forming a sixth exemplary structure according to an embodiment of the present disclosure. The sixth exemplary structure may be similar to the fifth exemplary structure shown in FIG. 40. However, the contact via structures in the method of forming the sixth exemplary structure are formed by forming contact via cavities and filling them with sacrificial contact via structures prior to bonding the first and second bonded assemblies to each other. After the bonding step, the sacrificial contact via structures are replaced with electrically conductive via structures.

Referring to FIG. 41A, the first and second bonded assemblies (1001, 1002) described above with respect to FIG. 24 are provided prior to bonding. The above described contact via cavities (457, 455, 459) are formed in each bonded assembly as described above. In one embodiment, the second through-die contact via cavities 459 and intra-die contact via cavities 455 are formed in both bonded assemblies (1001, 1002), while the first through-die contact via cavities 457 are optionally formed only through the first bonded assembly 1001.

Referring to FIG. 41B, the above described contact via cavities (457, 455, 459) are filled with respective sacrificial contact via structures (467, 465, 469). The sacrificial contact via structures (467, 465, 469) may comprise any one or more sacrificial materials that may be removed relative to the other materials of the bonded assemblies (1001, 1002). For example, the sacrificial contact via structures (467, 465, 469) may comprise a carbon material, such as amorphous carbon. Optionally, a dielectric liner, such as silicon oxide and a metallic barrier liner, such as TiN, WN, TaN or MoN may be deposited in the contact via cavities (457, 455, 459) prior to depositing the carbon sacrificial material into the contact via cavities (457, 455, 459). The sacrificial contact via structures (467, 465, 469) may be planarized by chemical mechanical polishing after deposition.

Referring to FIG. 41C, a dielectric capping layer 136 may be deposited over the top of the first and second memory die 900, including over the top of the sacrificial contact via structures (467, 465, 469). The dielectric capping layer 136 may comprise any suitable insulating layer, such as silicon oxide, silicon nitride, silicon carbonitride, etc.

Referring to FIG. 41D, at least the first controller-die semiconductor substrate 709 may be thinned as described above with respect to FIG. 25. The optional backside bonding-level dielectric layer 726 may be formed over the thinned backside surface of the controller-die semiconductor substrate 709, as described above. The first bonded assembly 1001 is then fusion bonded to the second bonded assembly 1002 at the first bonding interface 1010, as described above with respect to FIG. 26. If the optional backside bonding-level dielectric layer 726 is present, then it may be bonded to the dielectric capping layer 136 at the first bonding interface 1010 by dielectric-to-dielectric bonding to form the composite die (1001, 1002).

Referring to FIG. 41E, the sacrificial contact via structures (467, 465, 469) are selectively removed from the contact via cavities (457, 455, 459) after the bonding step. The sacrificial contact via structures (467, 465, 469) may be removed by ashing or selective etching. The horizontal portions of the backside bonding-level dielectric layer 726 and the dielectric capping layer 136 present at the first bonding interface 1010 may be removed by anisotropic etching between the steps of removing the sacrificial contact via structures (467, 465, 469) from the first and the second bonded assemblies (1001, 1002). Likewise, if the dielectric liner and the metallic barrier liner are present in the contact via cavities (457, 455, 459), then their horizontal portions at the bottom of the contact via cavities (457, 455, 459) are also removed by the anisotropic etching. Etching of the dielectric liners forms the above described insulating spacers (478, 476, 474). The etched barrier liner may comprise diffusion barrier and seed liners.

Referring to FIG. 41F, the contact via structures (488, 486, 484) are formed over the insulating spacers (478, 476, 474) in the contact via cavities (457, 455, 459). In one embodiment, the contact via structures (488, 486, 484) comprise copper via structures which are formed on the diffusion barrier and seed liners by electroless plating or electroplating. Subsequently, micro-bumps (725, 728) are formed on exposed upper ends of the contact via structures (488, 486, 484). The micro-bumps may comprise backside bonding structures (e.g., bonding pads) 728 and solder material portions (e.g., solder balls) 725 formed on the backside bonding structures 728.

Referring to FIG. 41G, the micro-bumps (725, 728) may be encapsulated in a bonding level dielectric layer 801. The composite die (1001, 1002) is turned upside down, and the bonding level dielectric layer 801 is placed on a support substrate 809, such as a glass substrate or a silicon wafer. If the second controller-die semiconductor substrate 709 has not been thinned previously, then it may be thinned at this step in the process to expose the top end of the second through-die contact via structure 484. The optional backside bonding-level dielectric layer 726 may be deposited over the thinned backside of the second controller-die semiconductor substrate 709, and then patterned to expose the top end of the second through-die contact via structure 484.

Referring to FIG. 41H, a frontside bonding structure (e.g., bonding pad) 728 may be formed on the top end of the second through-die contact via structure 484.

In summary, the method of FIG. 41A-41H includes forming a first through-die contact via cavity 457 that continuously extends through the first memory die 900 and the first memory-controller die 700 of the first bonded assembly 1001 prior to the fusion bonding of the first bonded assembly 1001 to the second bonded assembly 1002, and forming an intra-die contact via cavity 455 that extends through the least one dielectric material layer within the second bonded assembly 1002 and exposes the interconnect structure (e.g., pad) 152 within the second bonded assembly 1002 prior to the fusion bonding, as shown in FIG. 41A. The method also includes forming sacrificial contact via structures (465, 467) in the first through-die contact via cavity 457 and the intra-die contact via cavity 455 prior to the fusion bonding, as shown in FIG. 41B, and selectively removing the sacrificial contact via structures after the fusion bonding, as shown in FIG. 41E. The first through-die contact via cavity 457 and the intra-die contact via cavity 455 are aligned with each other after the fusion bonding to form a continuous inter-die cavity (455, 457), as shown in FIG. 41E. The first through-die contact via structure 488 is formed in the continuous inter-die cavity (455, 457) after the selectively removing the sacrificial contact via structures (465, 467) from the continuous inter-die cavity as shown in FIG. 41F.

Referring to all drawings of the present disclosure and various embodiments of the present disclosure, a semiconductor structure (e.g., the composite die (1001, 1002)) is provided, which comprises: a first bonded assembly 1001 including a first memory die 900 and a first memory-controller die 700 which is bonded to the first memory die 900, wherein the first memory die 900 includes a first alternating stack (32, 46) of first insulating layers 32 and first electrically conductive layers 46 and first memory stack structures 55 vertically extending through the first alternating stack (32, 46) and comprising a three-dimensional array of first memory elements (which may comprise portions of memory material layers 54), and wherein the first memory-controller die 700 includes a first memory controller circuit 720 configured to control operation of the three-dimensional array of first memory elements; a second bonded assembly 1002 bonded to the first bonded assembly 1001 at a first bonding interface and including a second memory die 900 and a second memory-controller die 700, wherein the second memory die 900 includes a second alternating stack (32, 46) of second insulating layers 32 and second electrically conductive layers 46 and second memory stack structures 55 vertically extending through the second alternating stack (32, 46) and comprising a three-dimensional array of second memory elements (which may comprise portions of memory material layers 54), and wherein the second memory-controller die 700 includes a second memory controller circuit 720 configured to control operation of the three-dimensional array of second memory elements; and a first through-die contact via structure 488 vertically extending through the first memory die 900, the first memory-controller die 700, the first bonding interface 1010, and at least one dielectric material layer (160 or 760) within the second bonded assembly 1002, and contacting an interconnect structure (e.g., 152 or 780) within the second bonded assembly 1002.

In one embodiment, the first memory die 900 is bonded to the first memory-controller die 700 by copper-to-copper bonding of respective first copper bonding pads (198, 798); the second memory die 900 is bonded to the second memory-controller die 700 by copper-to-copper bonding of respective second copper bonding pads (198, 798); the second bonded assembly 1002 is bonded to the first bonded assembly 1001 by fusion bonding; and the first bonded interface 1010 does not include any copper bonding pads.

In one embodiment, the interconnect structure 780 in the second bonded assembly 1002 is located within the second memory-controller die 700. In one embodiment, the second memory-controller die 700 is bonded to the first memory die 900 of the first bonded assembly 1001 at the first bonding interface 1010.

In one embodiment, the interconnect structure 152 in the second bonded assembly 1002 is located within the second memory die 900. In one embodiment, the second memory die 900 is bonded to the first memory-controller die 700 of the first bonded assembly 1001 at the first bonding interface 1010.

In one embodiment, the first memory stack structures 55 further comprise respective first vertical semiconductor channels 60; and the second memory stack structures 55 further comprise respective second vertical semiconductor channels 60.

In one embodiment, the semiconductor structure further comprises a third bonded assembly 1003 bonded to the second bonded assembly 1002 at a second bonding interface 1020 and including a third memory die 900 and a third memory-controller die 700. The third memory die 900 includes a third alternating stack (32, 46) of third insulating layers 32 and third electrically conductive layers 46 and third memory stack structures 55 vertically extending through the third alternating stack (32, 46) and comprising a three-dimensional array of third memory elements (which may comprise portions of memory material layers 54). The third memory-controller die 700 includes a third memory controller circuit 720 configured to control operation of the three-dimensional array of third memory elements. In one embodiment, the semiconductor structure comprises a second through-die contact via structure 484 vertically extending through the first memory die 900, the first memory-controller die 700, the second memory die 900, the second memory-controller die 700, the second bonding interface 1020, and at least one additional dielectric material layer within the third bonded assembly 1003, and contacting an additional interconnect structure (780 or 152) within the third bonded assembly 1003.

In one embodiment, the first memory-controller die 700 comprises a first controller-die semiconductor substrate 709; and the first through-die contact via structure 488 is laterally spaced from the first controller-die semiconductor substrate 709 by a first through-die insulating spacer 478. In one embodiment, the first through-die insulating spacer 478 comprises a first annular end surface contacting the interconnect structure (780 or 152) within the second bonded assembly 1002, and further comprises a second annular end surface located within a same horizontal plane as an end surface o the first through-die contact via structure 488 that is located on an opposite side of the first bonding interface 1010 with respect to the first bonded assembly 1001.

In one embodiment, the semiconductor structure also comprises a first counter-direction contact via structure 586 located within the second bonded assembly 1002 and including a distal horizontal surface located within a horizontal plane of the second bonded assembly 1002 that is most distal from the first bonding interface 1010. An electrically conductive path vertically extends from the first through-die via structure 488 to the first counter-direction contact via structure 586. In one embodiment shown in FIG. 40, the first counter-direction contact via structure 586 directly contacts the interconnect structure 152. In another embodiment shown in FIG. 37, the electrically conductive path comprises at least one additional interconnect structure 186 within the second bonded assembly 1002 that is interposed between the interconnect structure 152 and the first counter-direction contact via structure 586.

In one embodiment, the through-die contact via structure 488 comprises a first distal end surface located within a horizontal plane containing a distal horizontal surface of the first bonded assembly 1001 that is located on an opposite side of the bonding interface 1010. In one embodiment, the distal horizontal surface of the first bonded assembly 1001 is a horizontal surface of the first bonded assembly 1001 that is most distal from the bonding interface 1010. In one embodiment, the semiconductor structure comprises an intra-die contact via structure 486 vertically extending within one of the first memory die 900 and the first memory-controller die 700 and having a distal planar surface located within the horizontal plane containing the distal horizontal surface of the first bonded assembly 1001.

In one embodiment, each composite die (1001, 1002, and optionally 1003) illustrated in FIGS. 28, 31, 34, 37, 40 and 41H may comprise high bandwidth flash memory assembly (i.e., a high bandwidth flash memory chip) 2000. If the composite dies (1001, 1002, and optionally 1003) comprise a set of bonded wafers, the set of bonded wafers may be diced to form discrete semiconductor chips each comprising a high bandwidth flash memory assembly 2000. The high bandwidth flash memory assembly 2000 comprises two or more bonded assemblies 1000 of a respective memory die 900 and a respective memory-controller die 700.

By utilizing fusion bonding to form the composite die, the chip yield may be improved because precise alignment of copper bonding pads of the first and second bonded assemblies is not required during bonding of the first bonded assembly to the second bonded assembly. The chip yield is increased even higher if three or more bonded assemblies are bonded to each other by fusion bonding to form the composite die. In contrast, if copper-to-copper bonding is used to bond bonded assemblies to each other, then a misalignment between copper bonding pads of any two bonded assemblies during bonding may result in the entire chip containing the composite die being inoperative, which reduces the total chip yield.

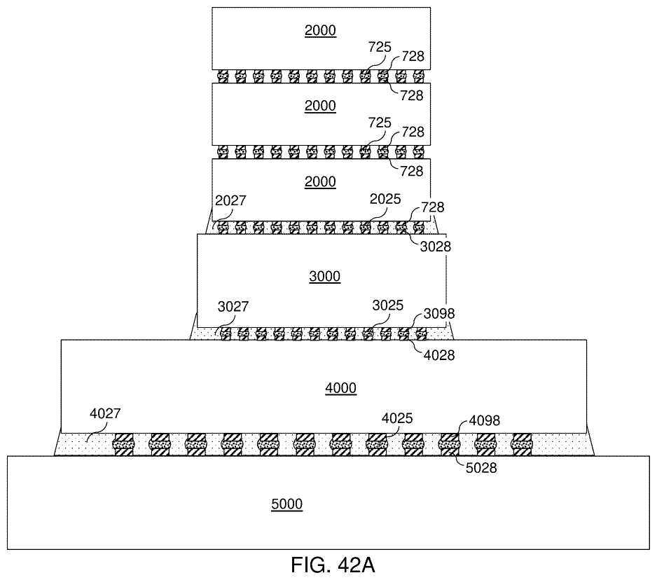

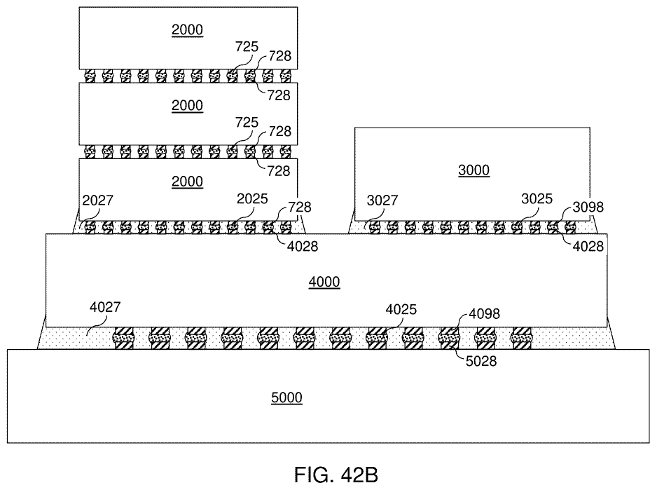

According to an aspect of the present disclosure, a plurality of high bandwidth flash memory assemblies 2000 can be bonded to additional semiconductor dies to provide a semiconductor package structure (3000, 4000, 5000) comprising package-side bump structures (3028, 4028). FIG. 42A and FIG. 42B illustrate exemplary configurations for semiconductor structures including a respective semiconductor package structure (3000, 4000, 5000). FIG. 42A is a vertical cross-sectional view of a first exemplary structure including multiple instances of the second exemplary bonded assembly according to an embodiment of the present disclosure. FIG. 42B is a vertical cross-sectional view of a second exemplary structure including multiple instances of the second exemplary bonded assembly according to an embodiment of the present disclosure.

The first exemplary structure illustrated in FIG. 42A includes a vertical stack of multiple high bandwidth flash memory assemblies 2000 that are stacked along a vertical direction, an optional system-level logic die 3000, an optional interposer 4000, and a packaging substrate 5000 according to an embodiment of the present disclosure. The multiple instances of a high bandwidth flash memory assembly 2000 are vertically stacked, and are bonded among one another trough arrays of inter-memory solder material portions 725. Each inter-memory solder material portions 725 may be bonded to a respective pair of controller-die backside bonding structures 728. The vertical stack of multiple high bandwidth flash memory assemblies 2000 may be bonded to the system-level logic die 3000.

The second exemplary structure illustrated in FIG. 42B includes multiple instances of a high bandwidth flash memory assembly 2000 that are stacked along a vertical direction, the optional system-level logic die 3000, the optional interposer 4000, and the packaging substrate 5000 according to an embodiment of the present disclosure. The vertical stack of multiple high bandwidth flash memory assemblies 2000 may be bonded to the interposer 4000.

The system-level logic die 3000, if present, controls the operation of the memory-controller dies 700 in each bonded assembly 1000 of the high bandwidth flash memory assembly 2000. The system-level logic die 3000 may comprise at least one of a central processing unit (CPU), a graphics processing unit (GPU), neural processing unit (NPU), and a digital signal processor (DSP). A bottommost instance of the high bandwidth flash memory assembly 2000 may be bonded to the system-level logic die 3000 or to the interposer 4000 through an array of solder material portions 2025. In one embodiment, the controller-die backside bonding structures 728 of the bottommost instance of the high bandwidth flash memory assembly 2000 may be bonded to top logic-die bump structures 3028 through an array of solder material portions 2025 as illustrated in FIG. 42A. Alternatively, the controller-die backside bonding structures 728 of the bottommost instance of the high bandwidth flash memory assembly 2000 may be bonded to top interposer bump structures 4028 through an array of solder material portions 2025 as illustrated in FIG. 42B. An underfill material portion 2027 may be applied around the array of solder material portions 2025.

The interposer 4000 may comprise any type of interposer known in the art. For example, the packaging substrate 5000 may comprise a ceramic interposer or an organic interposer. The system-level logic die 3000 may be bonded to the interposer 4000 through an array of solder material portions 3025. For example, the bottom logic-die bump structures 3098 of the system-level logic die 3000 may be bonded to top interposer bump structures 4028 of the interposer 4000 through the array of solder material portions 3025. An underfill material portion 3027 may be applied around the array of solder material portions 3025.

The packaging substrate 5000 may comprise any type of packaging substrate known in the art. For example, the packaging substrate 5000 may comprise a cored packaging substrate, a non-cored packaging substrate, etc. The interposer 4000 may be bonded to the interposer 4000 through an array of solder material portions 4025. For example, the bottom interposer bump structures 4098 of the interposer 4000 may be bonded to top substrate bump structures 5028 of the packaging substrate 5000 through the array of solder material portions 4025. An underfill material portion 4027 may be applied around the array of solder material portions 4025.

For each bonded assembly which may comprise a high bandwidth flash memory assembly 2000, a semiconductor package structure (2000, 3000, 4000, 5000) comprising package-side bump structures (3028, 4028) may be provided. The first memory-controller die 700 of the high bandwidth flash memory assembly 2000 comprises first controller-die backside bonding structures 728 located on an opposite side of the first controller-die copper bonding pads (which may comprise controller-die front bonding structures 798). The package-side bump structures (3028, 4028) are bonded to the first controller-die backside bonding structures 728 through an array of solder material portions 2025. In one embodiment, the semiconductor package structure (2000, 3000, 4000, 5000) comprises: an additional bonded assembly (e.g., an additional high bandwidth flash memory assembly 2000) that comprises a third memory die 900 and a fourth memory die 900 that are bonded to each other through hybrid bonding; or a processor die (e.g., the system-level logic die 3000) that comprises at least one of a central processing unit (CPU), a graphics processing unit (GPU), neural processing unit (NPU), and a digital signal processor (DSP).

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure, comprising:
a first bonded assembly including a first memory die and a first memory-controller die which is bonded to the first memory die, wherein the first memory die includes a first alternating stack of first insulating layers and first electrically conductive layers and first memory stack structures vertically extending through the first alternating stack and comprising a three-dimensional array of first memory elements, and wherein the first memory-controller die includes a first memory controller circuit configured to control operation of the three-dimensional array of first memory elements;
a second bonded assembly bonded to the first bonded assembly at a first bonding interface and including a second memory die and a second memory-controller die, wherein the second memory die includes a second alternating stack of second insulating layers and second electrically conductive layers and second memory stack structures vertically extending through the second alternating stack and comprising a three-dimensional array of second memory elements, and wherein the second memory-controller die includes a second memory controller circuit configured to control operation of the three-dimensional array of second memory elements; and
a first through-die contact via structure vertically extending through the first memory die, the first memory-controller die, the first bonding interface, and at least one dielectric material layer within the second bonded assembly, and contacting an interconnect structure within the second bonded assembly.

2. The semiconductor structure of claim 1, wherein:
the first memory die is bonded to the first memory-controller die by copper-to-copper bonding of respective first copper bonding pads;
the second memory die is bonded to the second memory-controller die by copper-to-copper bonding of respective second copper bonding pads;
the second bonded assembly is bonded to the first bonded assembly by fusion bonding; and
the first bonded interface does not include any copper bonding pads.

3. The semiconductor structure of claim 1, wherein the interconnect structure in the second bonded assembly is located within the second memory-controller die.

4. The semiconductor structure of claim 3, wherein the second memory-controller die is bonded to the first memory die of the first bonded assembly at the first bonding interface.

5. The semiconductor structure of claim 1, wherein the interconnect structure in the second bonded assembly is located within the second memory die.

6. The semiconductor structure of claim 5, wherein the second memory die is bonded to the first memory-controller die of the first bonded assembly at the first bonding interface.

7. The semiconductor structure of claim 1, wherein:
the first memory stack structures further comprise respective first vertical semiconductor channels; and
the second memory stack structures further comprise respective second vertical semiconductor channels.

8. The semiconductor structure of claim 1, further comprising a third bonded assembly bonded to the second bonded assembly at a second bonding interface and including a third memory die and a third memory-controller die, wherein the third memory die includes a third alternating stack of third insulating layers and third electrically conductive layers and third memory stack structures vertically extending through the third alternating stack and comprising a three-dimensional array of third memory elements, and wherein the third memory-controller die includes a third memory controller circuit configured to control operation of the three-dimensional array of third memory elements.

9. The semiconductor structure of claim 8, further comprising a second through-die contact via structure vertically extending through the first memory die, the first memory-controller die, the second memory die, the second memory-controller die, the second bonding interface, and at least one additional dielectric material layer within the third bonded assembly and contacting an additional interconnect structure within the third bonded assembly.

10. The semiconductor structure of claim 1, wherein:
the first memory-controller die comprises a first controller-die semiconductor substrate;
the first through-die contact via structure is laterally spaced from the first controller-die semiconductor substrate by a first through-die insulating spacer; and
the first through-die insulating spacer comprises a first annular end surface contacting the interconnect structure within the second bonded assembly, and further comprises a second annular end surface located within a same horizontal plane as an end surface of the first through-die contact via structure that is located on an opposite side of the first bonding interface with respect to the first bonded assembly.

11. The semiconductor structure of claim 1, further comprising a first counter-direction contact via structure located within the second bonded assembly and including a distal horizontal surface located within a horizontal plane of the second bonded assembly that is most distal from the first bonding interface, wherein an electrically conductive path vertically extends from the first through-die via structure to the first counter-direction contact via structure.

12. The semiconductor structure of claim 11, wherein the first counter-direction contact via structure directly contacts the interconnect structure.

13. The semiconductor structure of claim 11, wherein the electrically conductive path further comprises at least one additional interconnect structure within the second bonded assembly that is interposed between the interconnect structure and the first counter-direction contact via structure.

14. The semiconductor structure of claim 1, wherein:
the through-die contact via structure comprises a first distal end surface located within a horizontal plane containing a distal horizontal surface of the first bonded assembly that is located on an opposite side of the first bonding interface; and
the distal horizontal surface of the first bonded assembly is a horizontal surface of the first bonded assembly that is most distal from the first bonding interface.

15. The semiconductor structure of claim 14, further comprising an intra-die contact via structure vertically extending within one of the first memory die and the first memory-controller die and having a distal planar surface located within the horizontal plane containing the distal horizontal surface of the first bonded assembly.

16. A method of forming a semiconductor structure, comprising:
providing a first bonded assembly including a first memory die and a first memory-controller die which is bonded to the first memory die, wherein the first memory die includes a first alternating stack of first insulating layers and first electrically conductive layers and first memory stack structures vertically extending through the first alternating stack and comprising a three-dimensional array of first memory elements, and wherein the first memory-controller die includes a first memory controller circuit configured to control operation of the three-dimensional array of first memory elements;
providing a second bonded assembly including a second memory die and a second memory-controller die, wherein the second memory die includes a second alternating stack of second insulating layers and second electrically conductive layers and second memory stack structures vertically extending through the second alternating stack and comprising a three-dimensional array of second memory elements, and wherein the second memory-controller die includes a second memory controller circuit configured to control operation of the three-dimensional array of second memory elements;
fusion bonding the second bonded assembly to the first bonded assembly, wherein the second bonded assembly contacts the first bonded assembly at a first bonding interface; and
forming a first through-die contact via structure that continuously extends through the first memory die, the first memory-controller die, the first bonding interface, and at least one dielectric material layer within the second bonded assembly directly to an interconnect structure within the second bonded assembly.

17. The method of claim 16, further comprising:
providing a third bonded assembly including a third memory die and a third memory-controller die, wherein the third memory die includes a third alternating stack of third insulating layers and third electrically conductive layers and third memory stack structures vertically extending through the third alternating stack and comprising a three-dimensional array of third memory elements, and wherein the third memory-controller die includes a third memory controller circuit configured to control operation of the three-dimensional array of third memory elements;
fusion bonding the third bonded assembly to the second bonded assembly, wherein the third bonded assembly contacts the second bonded assembly at a second bonding interface; and
forming a second through-die contact via structure that continuously extends through the first bonded assembly, the second bonded assembly, the second bonding interface, and at least another dielectric material layer within the third bonded assembly directly to an additional interconnect structure within the third bonded assembly.

18. The method of claim 16, further comprising:
forming a first counter-direction contact via cavity that vertically extends from a distal horizontal plane of the second bonded assembly toward the first bonding interface, wherein the distal horizontal plane includes a horizontal surface of the second bonded assembly that is most distal from the first bonding interface; and
forming a first counter-direction contact via structure in the first counter-direction contact via cavity to form an electrically conductive path vertically extending from the first through-die via structure to the first counter-direction contact via structure.

19. The method of claim 16, further comprising:
forming a first through-die contact via cavity that continuously extends through the first memory die and the first memory-controller die prior to the fusion bonding;
forming an intra-die contact via cavity that extends through the least one dielectric material layer within the second bonded assembly and exposes the interconnect structure within the second bonded assembly prior to the fusion bonding;
forming sacrificial contact via structures in the first through-die contact via cavity and the intra-die contact via cavity prior to the fusion bonding; and
selectively removing the sacrificial contact via structures after the fusion bonding.

20. The method of claim 19, wherein:
the first through-die contact via cavity and the intra-die contact via cavity are aligned with each other after the fusion bonding to form a continuous inter-die cavity; and
the first through-die contact via structure is formed in the continuous inter-die cavity after the selectively removing the sacrificial contact via structures from the continuous inter-die cavity.
